(19) United States
(12) Patent Application Publication
(10) Pub. No.: US 2009/0014774 A1
(43) Pub. Date: Jan. 15, 2009

(54) NONVOLATILE SEMICONDUCTOR MEMORY ELEMENT AND NONVOLATILE SEMICONDUCTOR MEMORY DEVICE

(75) Inventor: Mizuki ONO, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/134,533

(22) Filed: Jun. 6, 2008

(30) Foreign Application Priority Data
Jun. 13, 2007 (JP) 2007-155919

(51) Int. Cl. H01L 29/788; H01L 29/792

(52) U.S. Cl. 257/316; 257/324; 257/E29.3; 257/E29.309

(57) ABSTRACT

A memory element includes: a semiconductor region formed in a semiconductor substrate; source and drain regions formed at a distance from each other in the semiconductor region; a first insulating layer formed on the semiconductor region between the source and drain regions; a charge accumulating layer formed on the first insulating layer, and having a stacked structure including at least three conductor films and inter-conductor insulating films provided between the adjacent conductor films, a dielectric constant of any one of the inter-conductor insulating films located at a greater distance from the semiconductor substrate being higher than that of any one of the inter-conductor insulating films closer to the semiconductor substrate, a dielectric constant of each of the inter-conductor insulating films being lower than that of the first insulating layer; and a second insulating layer formed on the charge accumulating layer, and having a higher dielectric constant than that of any one of the inter-conductor insulating films.

### CROSS-REFERENCE TO RELATED APPLICATION

This application is based upon and claims the benefit of priority from prior Japanese Patent Application No. 2007-155919 filed on Jun. 13, 2007 in Japan, the entire contents of which are incorporated herein by reference.

### BACKGROUND OF THE INVENTION

1. Field of the Invention

The present invention relates to a nonvolatile semiconductor memory element, and a nonvolatile semiconductor memory device that includes the nonvolatile semiconductor memory element.

2. Related Art

In a conventional nonvolatile semiconductor memory element, the potentials of the control gate electrode, the source and drain regions, and the semiconductor substrate are controlled so as to inject charges to or release charges from the charge accumulating layer provided between the channel region and the control gate electrode. By doing so, the amount of charges in the charge accumulating layer is adjusted, and the threshold voltage (the control gate voltage, based on which the source and drain of the element are switched between an ON state (a conductive state) and an OFF sate (a non-conductive state)) of the element is varied in accordance with the amount of charges. In this manner, information is stored in the element. In nonvolatile semiconductor memory elements of this type, the threshold voltage is switched between two values, so as to store information of 1 bit in each one memory element. Therefore, to achieve higher integration, information of more than 1 bit needs to be stored in each one memory element. To store multi-value information of more than 1 bit, the amount of charges in the charge accumulating layer should be finely controlled to obtain more than two different threshold voltage values. With more than two different threshold voltage values, information of more than 1 bit can be stored (as disclosed by Masayuki Ichige, et al., in “A novel self-aligned shallow trench isolation cell for 90 nm 4-Gbit NAND Flash EEPROMs”, in Technical Digest of 2003 Symposium on VLSI Technology, p.p 89-90, and Osama Khouri, et al., in “Program and Verify Word-Line Voltage Regulator for Multilevel Flash Memories” in Analog Integrated Circuits and Signal Processing, vol. 34 (2003) p.p 119-131, for example).

However, there are variations in device characteristics. By the above described method of obtaining more than two threshold voltage values by fine-controlling the amount of charges in the charge accumulating layer, it is necessary to perform a verifying operation. In a verifying operation, a check needs to be made to determine whether a desired threshold voltage is obtained, while the voltage to be applied to the control gate electrode is gradually increased during charge injection into the charge accumulating layer (as disclosed by Osama Khouri, et al., in “Program and Verify Word-Line Voltage Regulator for Multilevel Flash Memories”, in Analog Integrated Circuits and Signal Processing, vol. 34 (2003) p.p 119-131). As a result, the procedures for writing information have become complicated. This has been a great hindrance to high-speed operations of nonvolatile semiconductor memory elements and nonvolatile semiconductor memory devices formed with those nonvolatile semiconductor memory elements.

### SUMMARY OF THE INVENTION

The present invention has been made in view of these circumstances, and an object thereof is to provide a nonvolatile semiconductor memory element that does not require a verifying operation and can involve threshold voltages of more than two kinds, and a nonvolatile semiconductor memory device that includes such a nonvolatile semiconductor memory element.

A nonvolatile semiconductor memory element according to a first aspect of the present invention includes: a semiconductor substrate; a semiconductor region formed in the semiconductor substrate and containing an impurity of a first conductivity type; source and drain regions formed at a distance from each other in the semiconductor region, and contain an impurity of a second conductivity type; a first insulating layer formed on a portion of the semiconductor region, the portion being located between the source and drain regions; a charge accumulating layer formed on the first insulating layer, and having a stacked structure including at least three conductor films and inter-conductor insulating films provided between the adjacent conductor films, a dielectric constant of any one of the inter-conductor insulating films located at a greater distance from the semiconductor substrate being higher than a dielectric constant of any one of the inter-conductor insulating films closer to the semiconductor substrate, a dielectric constant of each of the inter-conductor insulating films being lower than a dielectric constant of the first insulating layer; a second insulating layer formed on the charge accumulating layer, and having a higher dielectric constant than the dielectric constant of any one of the inter-conductor insulating films; and a conductor layer formed on the second insulating layer.

A nonvolatile semiconductor memory element according to a second aspect of the present invention includes: a semiconductor substrate; a plate-like semiconductor region formed above the semiconductor substrate and containing an impurity of a first conductivity type; source and drain regions formed at a distance from each other in a longitudinal direction of the plate-like semiconductor region, and containing an impurity of a second conductivity type; a channel region provided in the plate-like semiconductor region located between the source region and the drain region; a first insulating layer covering a pair of faces of the channel region facing each other; a charge accumulating layer formed on a face of the first insulating layer on the opposite side from the channel region, and having a stacked structure including at least three conductor films and inter-conductor insulating films provided between the adjacent conductor films, a dielectric constant of any one of the inter-conductor insulating films located at a greater distance from the channel region being higher than a dielectric constant of any one of the inter-conductor insulating films closer to the channel region, a dielectric constant of each of the inter-conductor insulating films being lower than a dielectric constant of the first insulating layer; a second insulating layer formed on a face of the charge accumulating layer on the opposite side from the first insulating layer, and having a higher dielectric constant than the dielectric constant of any one of the inter-conductor insulating films; and a conductor layer formed on a face of the second insulating layer on the opposite side from the charge accumulating layer.

A nonvolatile semiconductor memory element according to a third aspect of the present invention includes: a semiconductor substrate; a semiconductor region formed in the semiconductor substrate and containing an impurity of a first conductivity type; source and drain regions formed at a distance from each other on the semiconductor region, and containing an impurity of a second conductivity type; a first insulating layer formed on a portion of the semiconductor region, the portion being located between the source and drain regions; a charge accumulating layer formed on the first insulating layer, and having a stacked structure including at least two stacked charge storing insulating films, a dielectric constant of any one of the charge storing insulating films located at a greater distance from the semiconductor substrate being higher than a dielectric constant of any one of the charge storing insulating films closer to the semiconductor substrate, a dielectric constant of each of the charge storing insulating films being lower than a dielectric constant of the first insulating layer; a second insulating layer formed on the charge accumulating layer, and having a higher dielectric constant than the dielectric constant of any one of the charge storing insulating films; and a conductor layer formed on the second insulating layer.

A nonvolatile semiconductor memory element according to a fourth aspect of the present invention includes: a semiconductor substrate; a plate-like semiconductor region formed on the semiconductor substrate and containing an impurity of a first conductivity type; source and drain regions formed at a distance from each other in a longitudinal direction of the plate-like semiconductor region, and containing an impurity of a second conductivity type; a channel region provided in the plate-like semiconductor region located between the source region and the drain region; a first insulating layer covering a pair of faces of the channel region facing each other; a charge accumulating layer formed a face of the first insulating layer on the opposite side from the channel region, and having a stacked structure including at least two stacked charge storing insulating films, a dielectric constant of any one of the charge storing insulating films located at a greater distance from the channel region being higher than a dielectric constant of any one of the charge storing insulating films closer to the channel region, a dielectric constant of each of the charge storing insulating films being lower than a dielectric constant of the first insulating layer; a second insulating layer formed on a face of the charge accumulating layer on the opposite side from the first insulating layer, and having a higher dielectric constant than the dielectric constant of any one of the charge storing insulating films; and a conductor layer formed on a face of the second insulating layer on the opposite side from the charge accumulating layer.

A nonvolatile semiconductor memory device according to a fifth aspect of the present invention includes: nonvolatile semiconductor memory elements being the same as the nonvolatile semiconductor memory element according to any one of first to fourth aspects, wherein the nonvolatile semiconductor memory elements are arranged in a lattice form, the source and drain regions of any two adjacent ones of the nonvolatile semiconductor memory elements in the same row are connected to each other, and the conductor layers of any two adjacent ones of the nonvolatile semiconductor memory elements in the same column are connected to each other.

### BRIEF DESCRIPTION OF THE DRAWINGS

FIG. 1 is a cross-sectional view of a nonvolatile semiconductor memory element according to a first embodiment;

FIGS. 2(a) and 2(b) are a cross-sectional view and an equivalent circuit diagram of a nonvolatile semiconductor memory element of a comparative example;

FIG. 3 is an equivalent circuit diagram of the nonvolatile semiconductor memory element of the first embodiment;

FIG. 4 shows changes in the threshold voltage V_{TH} of an element caused by increases in the voltage V_{CG} to be applied to the control gate electrode;

FIGS. 5 to 10 are cross-sectional views illustrating the procedures for manufacturing the nonvolatile semiconductor memory element of the first embodiment;

FIG. 11 is a cross-sectional view of a nonvolatile semiconductor memory element according to a second embodiment;

FIGS. 12 to 15 are cross-sectional views illustrating the procedures for manufacturing the nonvolatile semiconductor memory element of the second embodiment;

FIG. 16 is a cross-sectional view of a nonvolatile semiconductor memory element according to a third embodiment;

FIGS. 17 to 22 are cross-sectional views illustrating the procedures for manufacturing the nonvolatile semiconductor memory element of the third embodiment;

FIG. 23 is a perspective view of a nonvolatile semiconductor memory element according to a modification of the third embodiment;

FIG. 24 is a perspective view of a nonvolatile semiconductor memory element according to a fourth embodiment;

FIGS. 25 to 31 are perspective views illustrating the procedures for manufacturing the nonvolatile semiconductor memory element of the fourth embodiment;

FIG. 32 is a perspective view of a nonvolatile semiconductor memory element according to a fifth embodiment;

FIGS. 33 to 39 are perspective views illustrating the procedures for manufacturing the nonvolatile semiconductor memory element of the fifth embodiment;

FIG. 40 is a perspective view of a nonvolatile semiconductor memory element according to a sixth embodiment;

FIGS. 41 to 47 are perspective views illustrating the procedures for manufacturing the nonvolatile semiconductor memory element of the sixth embodiment;

FIG. 48 is a circuit diagram of a nonvolatile semiconductor memory device according to a seventh embodiment; and

FIG. 49 is a diagram for explaining the symbols in the circuit diagram of the nonvolatile semiconductor memory element of the seventh embodiment shown in FIG. 48.

### DESCRIPTION OF THE EMBODIMENTS

The following is a detailed description of embodiments of the present invention, with reference to the accompanying drawings. It should be noted that the present invention is not limited to the following embodiments, and various changes and modifications may be made to them to form a semiconductor memory device, a system LSI, and the likes.

### First Embodiment

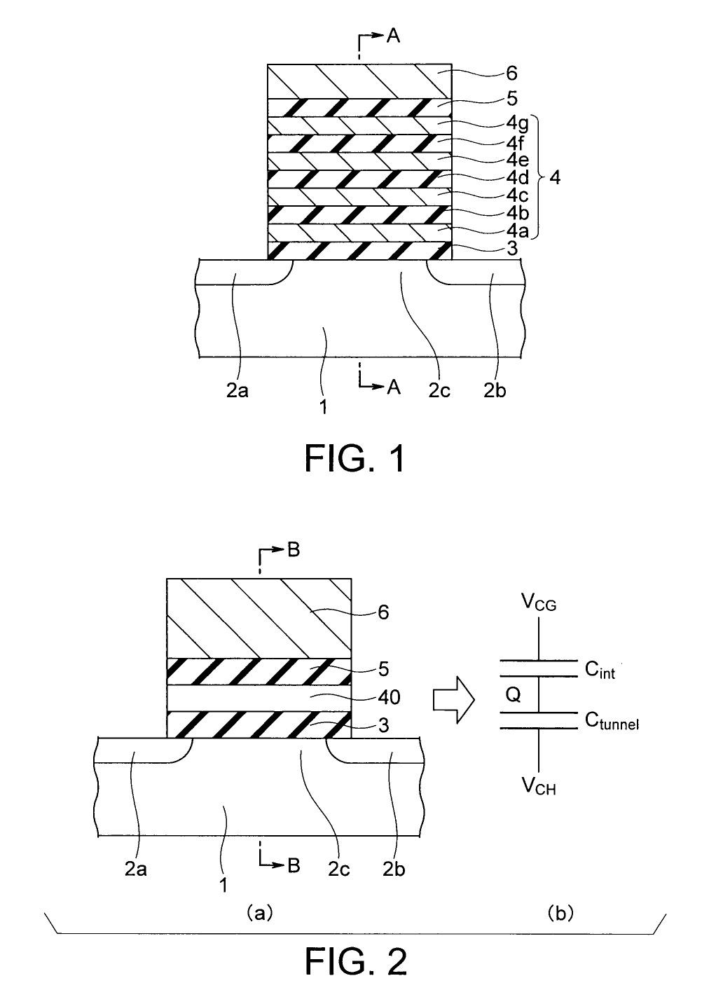

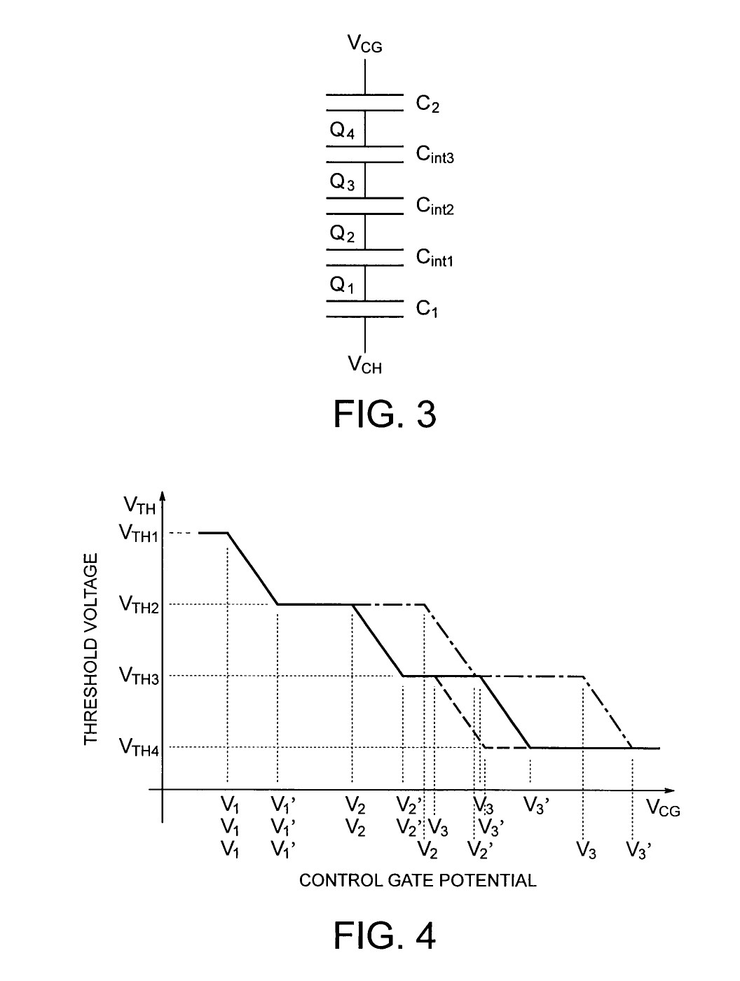

FIG. 1 shows a nonvolatile semiconductor memory element in accordance with a first embodiment of the present invention.

The nonvolatile semiconductor memory element of this embodiment has source and drain regions 2a and 2b formed at a distance from each other on a semiconductor substrate 1. A first insulating layer (a tunnel gate insulating film) 3 is formed on a region 2c of the semiconductor substrate 1 that is located between the source region 2a and the drain region 2b and serves as the channel. A charge accumulating layer 4 is formed on the first insulating layer 3. The charge accumulating layer 4 is a stacked structure that has more than one (four in this embodiment) stacked conductor films 4a, 4c, 4e, and 4g, and first to third inter-conductor insulating films 4b, 4d, and 4f provided between those conductor films. In other words, the charge accumulating layer 4 is a stacked structure that has the first conductor film 4a, the first inter-conductor insulating film 4b, the second conductor film 4c, the second inter-conductor insulating film 4d, the third conductor film 4e, the third inter-conductor insulating film 4f, and the fourth conductor film 4g, which are stacked in this order on the first insulating layer 3. Although the number of conductor films in the charge accumulating layer 4 is four in this embodiment, the charge accumulating layer 4 can be formed as long as at least three conductor films are stacked. A second insulating layer (an interelectrode insulating film) 5 is formed on the charge accumulating layer 4, and a conductor layer (a control gate electrode) 6 is formed on the second insulating layer 5. In FIG. 1, device isolating regions, interlayer insulating films, metal wires, and the likes are omitted and are not shown. Also, the scale size in FIG. 1 is not true to the actual scale, and the same applies to the other drawings. In the element of this embodiment, terminals that require wirings are the four terminals: the control gate electrode, the substrate, the source region, and the drain region. The element of this embodiment can operate with the same wiring structure as the wiring structure of a nonvolatile semiconductor memory element having a conventional structure, and does not require a more complicated wiring structure than the wiring structure of a nonvolatile semiconductor memory element having a conventional structure.

Among the inter-conductor insulating films 4b, 4d, and 4f of the charge accumulating layer 4 in this embodiment, an inter-conductor insulating film located at a longer distance from the semiconductor substrate 1 has a higher dielectric constant. The first insulating layer 3 and the second insulating layer 5 both have a higher dielectric constant than the dielectric constant of any of the inter-conductor insulating films 4b, 4d, and 4f of the charge accumulating layer 4. Accordingly, the dielectric constant of the third inter-conductor insulating film 4f is higher than the dielectric constant of the second inter-conductor insulating film 4d, and the dielectric constant of the second inter-conductor insulating film 4d is higher than the dielectric constant of the first inter-conductor insulating film 4b.

With this structure, the threshold voltage varies in a stepwise manner, as the voltage to be applied to the control gate electrode 6 increases, as described later. As a result, threshold voltages of more than two kinds can be obtained, and a verifying operation can be omitted. In the following, this aspect of the invention is explained in detail. Movement of charges between the conductor films of the charge accumulating layer 4 is caused by a tunnel current flowing through the inter-conductor insulating films formed between the conductor films of the charge accumulating layer 4. Therefore, movement of charges is not as discontinuous as in a case where charges move when the electric field in the inter-conductor insulating films is made larger than a particular value, but do not move when the electric field is made smaller than the particular value. Here, a MIM (Metal-Insulator-Metal) capacitor having an electrode on either side of a predetermined inter-conductor insulating film is described as an example. If the electric field in the inter-conductor insulating film that has the predetermined current value is set as the “write electric field”, it is possible to clearly define the “write electric field”. In this specification, the term, “write electric field”, has the meaning stated above.

As a comparative example, a nonvolatile semiconductor memory element that has a charge accumulating layer including a single-layer conductor film is taken. FIG. 2(a) is a cross-sectional view of the nonvolatile semiconductor memory element of this comparative example, taken along a line extending in a direction parallel to the current flowing in the channel region. The nonvolatile semiconductor memory element of the comparative example shown in FIG. 2(a) is the same as the nonvolatile semiconductor memory element of this embodiment shown in FIG. 1, except that the charge accumulating layer 4 is replaced with a charge accumulating layer 40 having a single-layer conductor film.

The stacked structure including the control gate electrode 6 is equivalent to the series connection between the capacitance Cᵢₙₜ of the interelectrode insulating film 5 and the capacitance Cₜᵤₙₙₑₗ of the tunnel gate insulating film 3, as shown in FIG. 2(b), which illustrates one-dimensionally the stacked structure taken along the line B-B of FIG. 2(a), for ease of explanation. The potential of the control gate electrode 6 is set as V_{CG}, the potential of the channel region 2c is set as V_{CH}, and the charges stored in the charge accumulating layer 40 is set as Q. Such a voltage condition that the electric field in the tunnel gate insulating film 3 becomes a write electric field is called the “write voltage condition” in this specification. Here, a case of an n-type element is taken as an example.

First, a writing operation is described. When the potential V_{CG} is set higher than the write voltage condition by ΔV, charges are injected into the charge accumulating layer 40. Since the sign of the charges injected here is a negative sign, the electric field in the tunnel gate insulating film 3 becomes weaker as the charges are injected. The charge injection is then stopped. In this situation, the charge amount Q in the charge accumulating layer 40 is expressed as Q=−Cᵢₙₜ×ΔV. Therefore, the threshold voltage V_{TH} of the element in this situation is expressed as:

V_{TH}=V_{TH0}−Q/Cᵢₙₜ=V_{TH0}+ΔV

where V_{TH0} represents the threshold voltage observed when no charges exist in the charge accumulating layer 40. Accordingly, the equation, ∂V_{TH}/∂V_{CG}=1, is established.

Likewise, in an erasing operation, the equation, ∂V_{TH}/∂V_{CG}=1, is also satisfied. Accordingly, as the potential V_{CG} is increased, the threshold voltage V_{TH} also becomes higher. Therefore, to control the threshold voltage with predetermined precision, it is necessary to control the potential of the control gate electrode 6 with the same precision as the predetermined precision at the time of writing and erasing. In reality, it is necessary to perform a verifying operation while gradually increasing the potential V_{CG} to be applied. When charges are released from the charge accumulating layer 40 at the time of erasing, a voltage that is negative with respect to the semiconductor substrate 1 may be applied to the control gate electrode 6, so as to release electrons toward the semiconductor substrate 1. Alternatively, a potential that is negative with respect to the source and drain regions 2a and 2b may be applied to the control gate electrode 6, so as to release electrons toward the source and drain regions 2a and 2b.

Explanation of the nonvolatile semiconductor memory element of this embodiment is now resumed.

A section of the structure taken along the line A-A of FIG. 1 is now described. Where the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, the first insulating layer 3, and the semiconductor substrate 1 are seen in a one-dimensional fashion for ease of explanation, the nonvolatile semiconductor memory element of this embodiment is equivalent to series connections of the capacitance C₁ of the first insulating layer 3, the capacitances Cᵢₙₜ₁, Cᵢₙₜ₂, and Cᵢₙₜ₃ of the first to third inter-conductor insulating films 4b, 4d, and 4f, and the capacitance C₂ of the second insulating layer 5.

Here, the potential of the control gate electrode 6 is represented by V_{CG}, and the potential of the channel region 2c is represented by V_{CH}. The amounts of charges stored in the first to fourth conductor films 4a, 4c, 4e, and 4g are represented by Q₁, Q₂, Q₃, and Q₄, respectively. The dielectric constants of the first to third inter-conductor insulating films 4b, 4d, and 4f are represented by kᵢₙₜ₁, kᵢₙₜ₂, and kᵢₙₜ₃, respectively. The electric fields in the first to third inter-conductor insulating films 4b, 4d, and 4f are represented by Eᵢₙₜ₁, Eᵢₙₜ₂, and Eᵢₙₜ₃, respectively. The dielectric constants of the first and second insulating layers 3 and 5 are represented by k₁ and k₂, respectively. The electric fields in the first and second insulating layers 3 and 5 are represented by E₁ and E₂, respectively. Here, an n-type element is taken as an example. Each of the conductor films is formed with a semiconductor, and the carriers in each of the conductor films are electrons. The same applies to a case where a p-type element is produced or the carriers in each of the conductor films are holes, if the voltage polarity is reversed.

First, a writing operation is described. In this example, electrons exist only in the first conductor film 4a among the conductor films 4a, 4c, 4e, and 4g. The threshold voltage in this situation is represented by V_{TH1}. Where the total amount of charges is represented by Q, the following relationships are established: Q₁=Q, Q₂=Q₃=Q₄=0. Since the carriers in each of the conductor films 4a, 4c, 4e, and 4g are electrons, Q is smaller than 0. Here, according to the Gauss Theorem of electrostatics, the following equation is established:

$$\begin{matrix}{k}_{int 1} \times {E}_{int 1} = {k}_{int 2} \times {E}_{int 2} \\ = {k}_{int 3} \times {E}_{int 2} \\ = {k}_{2} \times {E}_{2} \\ = {k}_{1} \times {E}_{1} + \vert Q \vert\end{matrix}$$

Since the relationships, kᵢₙₜ₁<kᵢₙₜ₂<kᵢₙₜ₃<k₁, k₂, are set as described above, the following inequation is established:

Eᵢₙₜ₁>Eᵢₙₜ₂>Eᵢₙₜ₂>E₁,E₂

Therefore, when V_{CG} is increased while V_{CH} is maintained at a fixed value, only the electric filed Eᵢₙₜ₁ in the first inter-conductor insulating film 4b reaches the write electric field. The potential V_{CG} of the control gate electrode 6 at this point is represented by V₁. When the potential V_{CG} is set higher than V₁ by ΔV, the charges stored in the first conductor film 4a pass through the first inter-conductor insulating film 4b, and flow into the second conductor film 4c. Since the sign of the charges injected at this point is a negative sign, the electric field in the first inter-conductor insulating film 4b becomes weaker as the charges are injected. The injection of the charges is then stopped. In this situation, the amount of charges Q′ stored in the second conductor film 4c is expressed as:

Q=−Cᵢₙₜ₁×ΔV

Accordingly, the threshold voltage V_{TH} of the element in this situation is expressed as:

V_{TH}=V_{TH1}+Q′/Cᵢₙₜ₁=V_{TH1}−ΔV

where V_{TH1} represents the threshold voltage observed when the amount of charges in the first conductor film 4a is Q. Accordingly, the equation, |∂V_{TH}/∂V_{CG}|=1, is satisfied in this voltage range. When V_{CG} is increased to satisfy the equation, V_{CG}=V₁−Q/Cᵢₙₜ₁, all the charges existing in the first conductor film 4a move into the second conductor film 4c, to satisfy the relationships, Q₂=Q, Q₁=Q₃=Q₄=0.

Hereinafter, V₁−Q/Cᵢₙₜ₁ will be represented by V₁′. Since Q is smaller than 0, V₁ is smaller than V₁′. When V_{CG}=V₁′ is established, the electric field Eᵢₙₜ₂ in the second inter-conductor insulating film 4d is weaker than the write electric field. This can be achieved by setting the dielectric constant kᵢₙₜ₂ of the second inter-conductor insulating film 4d sufficiently higher than the dielectric constant kᵢₙₜ₁ of the first inter-conductor insulating film 4b. When the potential V_{CG} is increased further, the electric field Eᵢₙₜ₂ of the second inter-conductor insulating film 4d reaches the write electric field. The potential V_{CG} at this point is represented by V₂.

When the potential V_{CG} is between V₁′ and V₂, the electric field Eᵢₙₜ₁ of the first inter-conductor insulating film 4b is stronger than the write electric field. However, no electrons exist in the first conductor film 4a in this situation. Therefore, charges do not move and do not pass through the first inter-conductor insulating film 4b. Also, the electric fields Eᵢₙₜ₂ and Eᵢₙₜ₃ in the second and third inter-conductor insulating films 4d and 4f, and the electric fields E₁ and E₂ in the first and second insulating layers 3 and 5 are all weaker than the write electric field. Therefore, charges do not move and do not pass through the second and third inter-conductor insulating films 4d and 4f, and charges do not move and do not pass through the first and second insulating layers 3 and 5, either. As a result, the threshold voltage V_{TH} is maintained at a fixed value. This fixed value is represented by V_{TH2}.

When the potential V_{CG} is set higher than V₂ by ΔV, the charges stored in the second conductor film 4c pass through the second inter-conductor insulating film 4d, and enter the third conductor film 4e. Since the sign of the charges injected at this point is a negative sign, the electric field in the second inter-conductor insulating film 4d becomes weaker as the charges are injected. The injection of the charges is then stopped. In this situation, the amount of charges Q″ stored in the third conductor film 4e is expressed as: Q″=−Cᵢₙₜ₂×ΔV. Accordingly, the threshold voltage V_{TH} of the element in this situation is expressed as:

V_{TH}=V_{TH2}+Q″/Cᵢₙₜ₂=V_{TH2}−ΔV

where V_{TH2} represents the threshold voltage observed when the amount of charges in the second conductor film 4c is Q. Accordingly, the equation, |∂V_{TH}/∂V_{CG}|=1, is satisfied in this voltage range. When V_{CG} is increased to satisfy the equation, V_{CG}=V₂−Q/Cᵢₙₜ₂, all the charges existing in the second conductor film 4c move into the third conductor film 4e, to satisfy the relationships, Q₃=Q, Q₁=Q₂=Q₄=0.

Hereinafter, V₂−Q/Cᵢₙₜ₂ will be represented by V₂′. Since Q is smaller than 0, V₂ is smaller than V₂′. When V_{CG}=V₂′ is established, the electric field Eᵢₙₜ₃ in the third inter-conductor insulating film 4f is weaker than the write electric field. This can be realized by setting the dielectric constant kᵢₙₜ₃ of the third inter-conductor insulating film 4f sufficiently higher than the dielectric constant kᵢₙₜ₂ of the second inter-conductor insulating film 4d. When the potential V_{CG} is increased further, the electric field Eᵢₙₜ₃ in the third inter-conductor insulating film 4f reaches the write electric field. The potential V_{CG} at this point is represented by V₃. When the potential V_{CG} is between V₂′ and V₃, the electric fields Eᵢₙₜ₁ and Eᵢₙₜ₂ in the first and second inter-conductor insulating films 4b and 4d are stronger than the write electric field. However, no electrons exist in the first and second conductor films 4a and 4c in this situation. Therefore, charges do not move and do not pass through the first and second inter-conductor insulating films 4b and 4d. Also, the electric field Eᵢₙₜ₃ in the third inter-conductor insulating film 4f and the electric fields E₁ and E₂ in the first and second insulating layers 3 and 5 are all weaker than the write electric field. Therefore, charges do not move and do not pass through the third inter-conductor insulating film 4f, and charges do not move and do not pass through the first and second insulating layers 3 and 5, either. As a result, the threshold voltage V_{TH} is maintained at a fixed value. This fixed value is represented by V_{TH3}. When the potential V_{CG} is set higher than V₃ by ΔV, the charges stored in the third conductor film 4e pass through the third inter-conductor insulating film 4f, and enter the fourth conductor film 4g. Since the sign of the charges injected at this point is a negative sign, the electric field in the third inter-conductor insulating film 4f becomes weaker as the charges are injected. The injection of the charges is then stopped. In this situation, the amount of charges Q′″ stored in the fourth conductor film 4g is expressed as:

Q′″=−Cᵢₙₜ₃×ΔV

Accordingly, the threshold voltage V_{TH} of the element in this situation is expressed as:

V_{TH}=V_{TH3}+Q′″/Cᵢₙₜ₃=V_{TH3}−ΔV

where V_{TH3} represents the threshold voltage observed when the amount of charges in the third conductor film 4e is Q. Accordingly, the equation, |∂V_{TH}/∂V_{CG}|=1, is satisfied in this voltage range.

When V_{CG} is further increased to satisfy the equation, V_{CG}=V₃−Q/Cᵢₙₜ₃, all the charges existing in the third conductor film 4e move into the fourth conductor film 4g, to satisfy the relationships, Q₄=Q, Q₁=Q₂=Q₃=0. Hereinafter, V₃−Q/Cᵢₙₜ₃ will be represented by V₃′. Since Q is smaller than 0, V₃ is smaller than V₃′. When V_{CG}=V₃′ is established, the electric fields E₁ and E₂ in the first and second insulating layers 3 and 5 are weaker than the write electric field. This can be realized by setting the dielectric constants k₁ and k₂ of the first and second insulating layers 3 and 5 sufficiently higher than the dielectric constant kᵢₙₜ₃ of the third inter-conductor insulating film 4f.

When the potential V_{CG} is increased further, the electric field E₁ in the first insulating layer 3 and the electric field E₂ in the second insulating layer 5 reach the write electric field. The potential V_{CG} at this point is represented by V₄. When the potential V_{CG} is between V₃′ and V₄, the electric fields Eᵢₙₜ₁, Eᵢₙₜ₂, and Eᵢₙₜ₃ in the first to third inter-conductor insulating films 4b, 4d, and 4f are stronger than the write electric field. However, no electrons exist in the first to third conductor films 4a, 4c, and 4e in this situation. Therefore, charges do not move and do not pass through the first to third inter-conductor insulating films 4b, 4d, and 4f. Also, the electric fields E₁ and E₂ in the first and second insulating layers 3 and 5 are both weaker than the write electric field. Therefore, charges do not move and do not pass through the first and second insulating layers 3 and 5. As a result, the threshold voltage V_{TH} is maintained at a fixed value. This fixed value is represented by V_{TH4}.

The solid line in FIG. 4 schematically shows the variation of the threshold voltage V_{TH} with respect to the variation of the potential V_{CG} to be applied to the control gate electrode in the above described operation. The broken line and the dot-and-dash line will be described later.

In FIG. 4, V₄ is not shown on the abscissa axis, which does not include the value of V₄. As can be seen from FIG. 4, in the nonvolatile semiconductor memory element of this embodiment, the threshold voltage V_{TH} varies in a stepwise manner as the potential V_{CG} increases. This is a fact newly discovered through this experiment.

Since the charge accumulating layer 4 has four conductor films in this embodiment, the threshold voltage of a nonvolatile semiconductor memory element can have four different values. As a result, four values can be stored in each one nonvolatile semiconductor memory element. Generally, the threshold voltage of a nonvolatile semiconductor memory element can have N values, if N conductor films are provided in the charge accumulating layer, with N being an integer. In such a case, N values can be stored in each one nonvolatile semiconductor memory element. If N is 3 or larger, the threshold voltage of each nonvolatile semiconductor memory element can have three or more values, and information of more than 1 bit can be stored in each one nonvolatile semiconductor memory element. By virtue of this aspect of the present invention, the memory capacity can be increased. Also, as mentioned above, the threshold voltage V_{TH} varies in a stepwise manner as the potential V_{CG} to be applied to the control gate electrode 6 increases. Accordingly, a verifying operation can be eliminated. Thus, a nonvolatile semiconductor memory element that has a larger memory capacity and is capable of performing higher-speed operations can be realized. Particularly, in a case where N represents a power of two, or where the value obtained by adding “1” to the number of inter-conductor insulating films equal to a power of two, the amount of information that can be stored in each one nonvolatile semiconductor memory element is equivalent to an integral number of bits. Accordingly, information processing becomes easier.

### (Manufacturing Method According to First Embodiment)

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

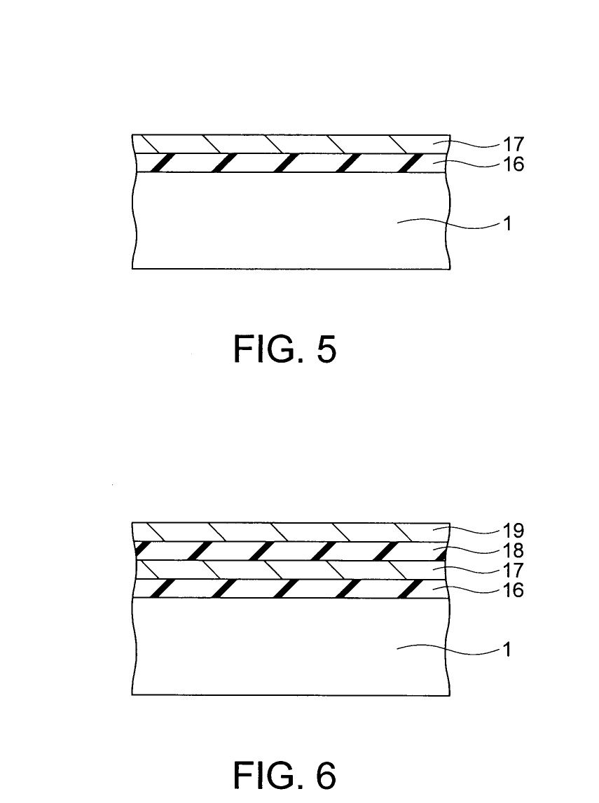

First, as shown in FIG. 5, after device isolating regions (not shown) are formed in the semiconductor substrate 1, B (boron) ions are injected with an energy of 30 keV and at a concentration of 1×10¹² atoms/cm², for example. Heat treatment is then carried out at 1050° C. for 30 seconds, for example. A first LaAlO₃ (lanthanum aluminate) film 16 of 30 nm in thickness is formed on the semiconductor substrate 1 by chemical vapor deposition (hereinafter referred to as “CVD”), for example. A 5-nm thick first polycrystalline silicon film 17 containing As (arsenic) or the like at a concentration of 2×10¹⁸ atoms/cm³ is then formed on the first LaAlO₃ film 16 by CVD, for example.

As shown in FIG. 6, a Si₃N₄ (silicon nitride) film 18 of 8 nm in thickness is then formed on the first polycrystalline silicon film 17 by CVD, for example. A 5-nm thick second polycrystalline silicon film 19 containing As or the like at a concentration of 2×10¹⁸ atoms/cm³ is then formed on the Si₃N₄ film 18 by CVD, for example.

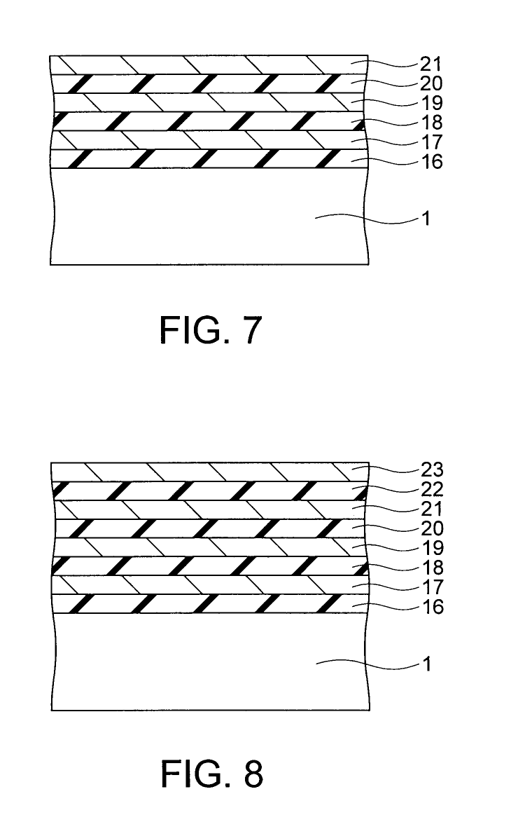

As shown in FIG. 7, a Al₂O₃ (aluminum oxide) film 20 of 10 nm in thickness is then formed on the second polycrystalline silicon film 19 by CVD, for example. A 5-nm thick third polycrystalline silicon film 21 containing As or the like at a concentration of 2×10¹⁸ atoms/cm³ is then formed on the Al₂O₃ film 20 by CVD, for example.

As shown in FIG. 8, a HfO₂ (hafnium oxide) film 22 of 25 nm in thickness is then formed on the third polycrystalline silicon film 21 by CVD, for example. A 5-nm thick fourth polycrystalline silicon film 23 containing As or the like at a concentration of 2×10¹⁸ atoms/cm³ is then formed on the HfO₂ film 22 by CVD, for example.

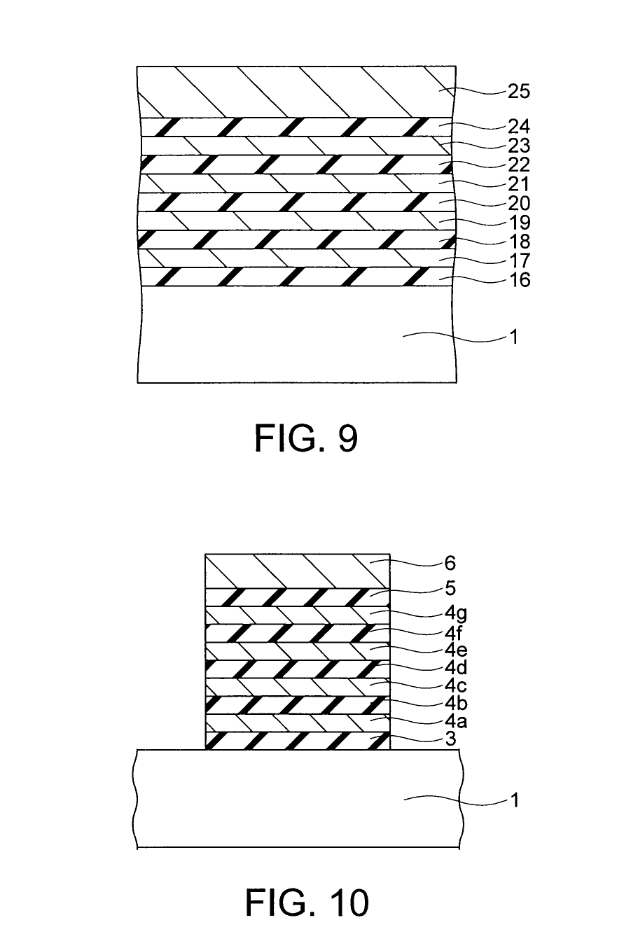

As shown in FIG. 9, a second LaAlO₃ film 24 of 30 nm in thickness is formed on the fourth polycrystalline silicon film 23 by CVD, for example. A W (tungsten) film 25 of 50 nm in thickness is then formed on the second LaAlO₃ film 24 by CVD, for example.

As shown in FIG. 10, patterning is then performed by reactive ion etching (hereinafter referred to as “RIE”) on the tungsten film 25, the second LaAlO₃ film 24, the fourth polycrystalline silicon film 23, the HfO₂ film 22, the third polycrystalline silicon film 21, the Al₂O₃ film 20, the second polycrystalline silicon film 19, the Si₃N₄ film 18, the first polycrystalline silicon film 17, and the first LaAlO₃ film 16, so as to form the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, and the first insulating layer 3.

After that, As ions are injected with an energy of 5 keV and at a concentration of 1×10¹⁵ atoms/cm², for example. Heat treatment is then carried out to form the source and drain regions 2a and 2b. An interlayer insulating film forming procedure, a wiring procedure, and the likes are then carried out in the same manner as in a case where a conventional nonvolatile semiconductor memory element is manufactured by known techniques. In this manner, the nonvolatile semiconductor memory element of this embodiment shown in FIG. 1 is completed.

Although an n-type element has been described in this embodiment, the same manufacturing method as above can be utilized to manufacture a p-type element if the conductivity type of the impurities is the opposite type of an n-type element, and a complementary-type element if impurities are injected into a predetermined region in the substrate by a photo lithography technique or the like. The above described method may also be utilized to form a semiconductor device that includes one of those elements as its component.

Also, only the procedures for manufacturing a nonvolatile semiconductor memory element have been described in this embodiment. However, the above described method may be utilized in cases where a nonvolatile semiconductor memory element is formed as a component of a semiconductor device that also includes an active element such as a field effect transistor, a bipolar transistor, or a single-electron transistor, a passive element such as a resistor, a diode, an inductor, or a capacitor, an element including a ferroelectric material, or an element including a magnetic material. The method may also be utilized in cases where a nonvolatile semiconductor memory element is formed as a component of an OEIC (opto-electrical integrated circuit) or a MEMS (micro-electro mechanical system). It is of course possible that peripheral circuits of a nonvolatile semiconductor memory element can be formed at the same time by the above method.

In the above described embodiment, a nonvolatile semiconductor memory element is formed on a bulk substrate. However, the same effects as above can be achieved if a nonvolatile semiconductor memory element is formed on a SOI (Semiconductor on Insulator) substrate.

Also, in this embodiment described above, As is used as the impurity for forming the n-type semiconductor layer, and B is used as the impurity for forming the p-type semiconductor layer. However, it is also possible to use some other V-group impurity for forming the n-type semiconductor layer, and use some other III-group impurity for forming the p-type semiconductor layer. Introduction of those III-group and V-group impurities may be performed with the use of compounds containing those impurities.

In this embodiment, introduction of impurities into the source and drain is performed through ion injection. However, it is possible to utilize a technique other than the ion injection technique, such as a solid phase diffusion technique or a gas phase diffusion technique. It is also possible to utilize a technique by which a semiconductor containing impurities is deposited or grown. In this embodiment, the conductor films are formed by depositing semiconductors containing impurities. However, it is possible to introduce impurities by an ion injection technique, a solid phase diffusion technique, or a gas phase diffusion technique, after semiconductor films formed. An ion injection technique has the advantage that a complementary-type semiconductor device including an n-type element and a p-type element can be easily formed. Deposition of semiconductors containing impurities and a solid phase diffusion technique and a gas phase diffusion technique have the advantage that a high impurity concentration can be easily achieved.

In this embodiment, impurity introduction for adjusting the threshold voltage of the element is not performed. However, impurity introduction, other than the impurity introduction for forming the wells, may be performed to adjust the threshold voltage. By performing such impurity introduction, the threshold voltage can be readily set at a desired value. Also, the manufacturing procedures can be simplified in this embodiment.

Also, in this embodiment, an element having a single-drain structure has been described. However, it is possible to form an element having an extension structure, for example. It is also possible to form an element having a halo structure or the like. Those structures are preferred, as the resistivity of the element to a short-channel effect becomes higher.

In this embodiment, the source and drain regions 2a and 2b are formed after the processing of the stacked structure consisting of the control gate electrode 6 and the first insulating layer 3. However, this manufacturing order is not essential, and may be reversed. Depending on the materials of the control gate electrode 6 and the first insulating layer 3, it might not be preferable that heat treatment is carried out on those components. In such a case, it is preferable that the procedures starting from the introduction of impurities into the source and drain regions 2a and 2b to the activating procedure are carried out prior to the processing of the control gate electrode 6 and the first insulating layer 3.

In this embodiment, the conductor films 4a, 4c, 4e, and 4g of the charge accumulating layer 4 are made of polycrystalline silicon. However, the conductor films 4a, 4c, 4e, and 4g may be made of some other material. For example, it is possible to use a metal such as tungsten, titanium, or tantalum, or a compound such as a metal nitride such as tungsten nitride, titanium nitride, or tantalum nitride, or a metal silicide such as tungsten silicide, titanium silicide, or a tantalum silicide. It is also possible to use a semiconductor other than polycrystalline silicon, such as single-crystal silicon or amorphous silicon, to form the conductor films 4a, 4c, 4e, and 4g. Alternatively, stacked layers of those materials may be used. The same applies to the control gate electrode 6.

If the conductor films 4a, 4c, 4e, and 4g of the charge accumulating layer 4 are made of a semiconductor, the threshold voltage varies in a stepwise manner with an increase of the control gate electrode, as shown in FIG. 4. Accordingly, a verifying operation can be skipped. Thus, information of more than one bit can be stored in one nonvolatile semiconductor memory element, and the storing operation can be simplified. Also, the charge accumulating layer 4 may be made of a particulate metal, a semiconductor, or a compound of those materials. If the control gate electrode 6 is made of a metal or a compound containing a metal, the resistance of the control gate electrode 6 is reduced, and a high-speed operation can be performed by the element. Furthermore, if the control gate electrode 6 and the conductor films 4a, 4c, 4e, and 4g of the charge accumulating layer 4 are made of metal, an oxidizing reaction can be prevented. In such a case, high controllability can be achieved in controlling the interfaces as in a case where the states at the interfaces between the first insulating layer 3, the second insulating layer 5, the inter-conductor insulating films 4b, 4d, and 4f, the control gate electrode 6, the channel region 2c, and the conductor films of the charge accumulating layer are restrained. If at least a part of the control gate electrode 6 and the charge accumulating layer 4 is made of a semiconductor such as polycrystalline silicon, it is easy to control the work function. In such a case, it is also easy to adjust the threshold voltage of the element.

In this embodiment, the control gate electrode 6 and the charge accumulating layer 4 are formed by performing anisotropic etching on deposited materials of the control gate electrode 6 and the charge accumulating layer 4. However, it is also possible to form the control gate electrode 6 and the charge accumulating layer 4 by an embedding technique such as the damascene process. If the source and drain regions 2a and 2b are formed prior to the formation of the control gate electrode 6 and the charge accumulating layer 4, it is preferable that the damascene process is used, because the source and drain 2a and 2b are formed in a self-aligning manner with respect to the control gate electrode 6 and the charge accumulating layer 4.

In this embodiment, the lengths of the upper portion and the lower portion of the control gate electrode 6 measured in the principal direction of the current flowing in the element (the horizontal direction of FIG. 1) are the same. However, this aspect of this embodiment is not essential in the present invention. For example, the control gate electrode 6 may have a long “T”-like shape, having the upper portion longer than the lower portion. This arrangement has the advantage that the gate resistance can be reduced.

Although not clearly mentioned in this embodiment, the metal layer for forming wires may be formed by a sputtering technique or a deposition technique, for example. Alternatively, it is possible to form the metal layer by a selective growth technique or the damascene process, for example. The material of the wiring metal may be Al (aluminum) containing silicon or a metal such as Cu (copper), for example. Particularly, Cu is preferred, having lower resistivity.

Although a silicidation procedure is not mentioned in this embodiment, a silicide layer may be formed on the source and drain regions 2a and 2b. Alternatively, a layer containing metal may be deposited or grown on the source and drain regions 2a and 2b. This arrangement has the advantage that the resistance of the source and drain regions 2a and 2b is reduced. In a case where the control gate electrode 6 is made of polycrystalline silicon or the like, silicidation may be performed on the control gate electrode 6. In such a case, the gate resistance is reduced through the silicidation.

It is also possible to employ an elevated structure. With an elevated structure, the resistance of the source and drain regions can be reduced.

Also, in this embodiment, the control gate electrode 6 is exposed at its upper portion. However, an insulating material such as silicon oxide, silicon nitride, or silicon oxynitride may be provided at the upper portion. Particularly, in a case where the control gate electrode 6 is made of a material containing metal and a silicide layer is formed on the source and drain regions 2a and 2b, or in a case where the control gate electrode 6 needs to be protected during the manufacturing process, it is necessary to provide a protecting material such as silicon oxide, silicon nitride, or silicon oxynitride at the upper portion of the control gate electrode 6.

Also, in this embodiment, the first and second insulating layers 3 and 5 are lanthanum aluminate films, and the first through third inter-conductor insulating films 4b, 4d, and 4f are a silicon nitride film, an aluminum oxide film, and a hafnium oxide film, respectively. However, an insulating film such as a silicon oxide film or a silicon oxynitride film, or a stacked film layer consisting of those insulating films may be used as one of the first and second insulating layers 3 and 5 and the first to third inter-conductor insulating films 4b, 4d, and 4f. If nitrogen exists in an insulating film, diffusion of impurities into the substrate 1 can be prevented in a case where polycrystalline silicon containing impurities is used as the control gate electrode 6 or the conductor films 4a, 4c, 4e, and 4g of the charge accumulating layer 4. Accordingly, variations of the threshold voltage can be restricted. If silicon oxide is used for one of the first and second insulating films 3 and 5 and the first to third inter-conductor insulating films 4b, 4d, and 4f, the interface state at the interface between any of the insulating layers 3 and 5 and the insulating films 4b, 4d, and 4f, and any of the conductor films 4a, 4c, 4e, and 4g, the control gate electrode 6, and the substrate 1 is small, and the amount of fixed charges in the insulating layers and insulating films is small. Thus, variations of device characteristics can be restricted.

In a case where an oxide of a material is used as an insulating layer or an insulating film, a film of the material is first formed, and oxidation may be then performed on the film. Alternatively, the film may be exposed to an oxygen gas in an excited state that does not always involve a temperature rise. It is preferable that the oxide film is formed by exposing the film to an oxygen gas in an excited state that does not involve a temperature rise, because a change in the impurity concentration distribution due to diffusion of the impurities in the channel region can be prevented. In a case where silicon oxynitride is used, a silicon oxide film is first formed, and nitrogen is then introduced into the insulating film by exposing the film to a gas containing nitrogen in a temperature rising state or an excited state. It is preferable that the silicon oxide film is exposed to a nitrogen gas in an excited state that does not involve a temperature rise, because a change in the impurity concentration distribution due to diffusion of the impurities in the channel region can be prevented. Alternatively, a silicon nitride film is first formed, and oxygen is then introduced into the insulating film by exposing the film to a gas containing oxygen in a temperature rising state or an excited state. It is preferable that the silicon nitride film is exposed to an oxygen gas in an excited state that does not involve a temperature rise, because a change in the impurity concentration distribution due to diffusion of the impurities in the channel region can be prevented.

For one of the first and second insulating layers 3 and 5 and the first to third inter-conductor insulating films 4b, 4d, and 4f, it is also possible to use an oxide of a metal such as Hf (hafnium), Zr (zirconium), Ti (titanium), Sc (scandium), Y (yttrium), Ta (tantalum), Al, La (lanthanum), Ce (cerium), Pr (praseodymium), or a lanthanoid, a silicate material containing one of those elements or some other elements, an insulating film formed by adding nitrogen to the above oxide film or the silicate film, a high-dielectric film, or an insulating film formed with a stacked film layers consisting of some of those materials.

This embodiment is characterized in that the inter-conductor insulating films 4b, 4d, and 4f, the first insulating layer 3, and the second insulating layer 5 have different dielectric constants from one another. To maintain this feature of this embodiment, the inter-conductor insulating film 4f closest to the control gate electrode 6 among the inter-conductor insulating films 4b, 4d, and 4f, the first insulating layer 3, and the second insulating layer 5 need to have high dielectric constants. Particularly, the first insulating layer 3 and the second insulating layer 5 need to have high dielectric constants. For example, an oxide of a metal such as Hf, Zr, Ti, Sc, Y, Ta, Al, La, Ce, Pr, or a lanthanoid, a silicate material containing one of those elements or some other elements, an insulating film formed by adding nitrogen to the above oxide film or the silicate film, and a high-dielectric film have higher dielectric constants than silicon oxide, silicon nitride, and silicon oxynitride. Accordingly, it is preferable that those materials are used for the inter-conductor insulating film 4f closest to the control gate electrode 6 among the inter-conductor insulating films 4b, 4d, and 4f, the first insulating layer 3, and the second insulating layer 5. Particularly, it is preferable that those materials are used for the first insulating layer 3 and the second insulating layer 5.

If the inter-conductor insulating films 4b, 4d, and 4f, and the first and second insulating layers 3 and 5 have small film thicknesses, a tunnel current flows through the insulating films even when there is no need to have a tunnel current flowing through the insulating films. As a result of this, a change is caused in the stored information. In other words, the information retention time becomes shorter. Therefore, the film thicknesses of the inter-conductor insulating films 4b, 4d, and 4f, and the first and second insulating layers 3 and 5 should preferably be larger than a certain thickness. Also, to strengthen the capacitive coupling formed between the control gate electrode 6 and the channel region 2c via the charge accumulating layer 4, the inter-conductor insulating films 4b, 4d, and 4f, and the first and second insulating layers 3 and 5 should preferably have higher dielectric constants than silicon oxide that has conventionally been used. Also, the insulating films are not necessarily formed by CVD, but may be formed by some other method such as a thermal oxidation technique, a vapor deposition technique, a sputtering technique, or an epitaxial growth technique.

To make the dielectric constants of the insulating films differ from one another by using conventional materials and a conventional process, the following combinations are preferred. The inter-conductor insulating film 4b is made of silicon oxide, silicon nitride, or silicon oxynitride. The inter-conductor insulating film 4d is made of aluminum oxide. The inter-conductor insulating film 4f is made of hafnium oxide, zirconium oxide, hafnium silicate, or zirconium silicate. The first and second insulating layers 3 and 5 are made of lanthanum aluminate.

The thicknesses of the insulating layers 3 and 5, the insulating films 4b, 4d, and 4f, the conductor films 4a, 4c, 4e, and 4g, and the control gate electrode 6 are not limited to the values set in this embodiment. However, the intensity of capacitive coupling is determined not by geometric film thicknesses but by equivalent oxide thicknesses, and the difference in threshold voltage is proportional to the equivalent oxide thicknesses of the inter-conductor insulating films in a case where charges exist in each conductor film. Accordingly, when the respective inter-conductor insulating films have the same equivalent oxide thickness, the threshold voltage varies at equal intervals. Thus, signal processing becomes easier. In this embodiment, the first inter-conductor insulating film 4b is a 8-nm thick Si₃N₄ film, the second inter-conductor insulating film 4d is a 10-nm thick Al₂O₃ film, and the third inter-conductor insulating film 4f is a 25-nm thick HfO₂ film. With those materials, the equivalent oxide thicknesses of the inter-conductor insulating films are substantially the same, which is 4 nm. Accordingly, a nonvolatile semiconductor memory element in which the threshold voltage varies at equal intervals can be realized. As described above, if the equivalent oxide thicknesses are substantially the same, or if the values obtained by rounding off the equivalent oxide thicknesses (nm) to the decimal point are the same, the threshold value varies at equal intervals.

In this embodiment, the first and second insulating layers 3 and 5 are formed with 30-nm thick LaAlO₃ films. Where LaAlO₃ films are used as the first and second insulating layers 3 and 5, and the above described Si₃N₄ film, Al₂O₃ film, and HfO₂ film are used as the inter-conductor insulating films 4b, 4d, and 4f, a nonvolatile semiconductor memory element in which the dielectric constants of the first and second insulating layers 3 and 5 are higher than the dielectric constants of the inter-conductor insulating films is realized.

Although gate sidewalls are not mentioned in the above described embodiment, it is possible to provide sidewalls to the control gate electrode 6 and the charge accumulating layer 4. Particularly, if gate sidewalls made of a high-dielectric material are provided in a structure in which the first insulating layer 3, the second insulating layer 5, and the inter-conductor insulating films 4b, 4d, and 4f are made of high-dielectric materials, the electric fields in the first and second insulating layers 3 and 5 and the inter-conductor insulating films 4b, 4d, and 4f are weakened in the vicinities of the lower ends of the control gate electrode 6 and the conductor films 4a, 4c, 4e, and 4g, as disclosed in Japanese Patent Publication No. 3658564. Accordingly, the reliability of the first and second insulating layers 3 and 5 and the inter-conductor insulating films 4b, 4d, and 4f is increased, and erroneous write and inadvertent erase can be prevented.

In this embodiment, post-oxidation after the formation of the control gate electrode 6 and the charge accumulating layer 4 has not been described. However, a post-oxidation process may be carried out, if it is compatible with the materials of the control gate electrode 6, the charge accumulating layer 4, the first and second insulating layers 3 and 5, the inter-conductor insulating films 4b, 4d, and 4f. Other than post-oxidation, a chemical solution process or exposure to a reactive gas is performed to round the corner portions of the control gate electrode 6 and the conductor films 4a, 4c, 4e, and 4g. If such a process can be performed, the electric fields at the lower end portions of the control gate electrode 6 and the conductor films 4a, 4c, 4e, and 4g are weakened. Accordingly, the reliability of the first insulating layer 3, the second insulating layer 5, and the inter-conductor insulating films 4b, 4d, and 4f is increased.

Although not mentioned in this embodiment, silicon oxide films may be used as interlayer insulating films, or films made of a low-k material other than silicon oxide may be used as interlayer insulating films. If the dielectric constants of interlayer insulating films are low, the parasitic capacitance of the element is also low. Thus, high-speed operations can be performed with the element.

Although contact holes have not been mentioned, it is possible to form self-aligning contacts. With self-aligning contacts, the area of each element can be reduced, and higher integration can be achieved.

### Second Embodiment

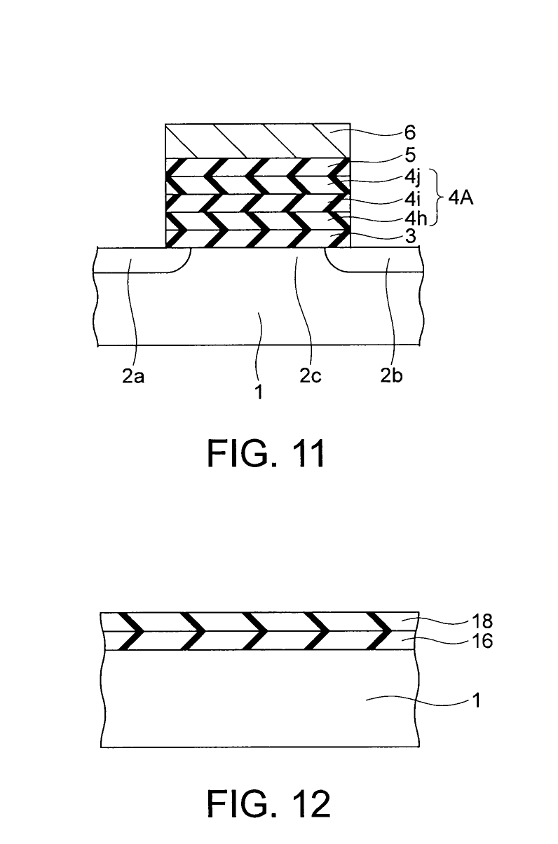

FIG. 11 is a cross-sectional view of a nonvolatile semiconductor memory element in accordance with a second embodiment of the present invention. The nonvolatile semiconductor memory element of this embodiment has source and drain regions 2a and 2b formed at a distance from each other on a semiconductor substrate 1. A first insulating layer 3 is formed on a region 2c of the semiconductor substrate 1 that is located between the source region 2a and the drain region 2b and serves as the channel. A charge accumulating layer 4A is formed on the first insulating layer 3. The charge accumulating layer 4A has a first charge storing insulating film 4h formed on the first insulating layer 3, a second charge storing insulating film 4i formed on the first charge storing insulating film 4h, and a third charge storing insulating film 4j formed on the second charge storing insulating film 4i. A control gate electrode 6 is formed on the charge accumulating layer 4A to sandwich a second insulating layer 5. Here, the dielectric constant of the second charge storing insulating film 4i is set higher than the dielectric constant of the first charge storing insulating film 4h, the dielectric constant of the third charge storing insulating film 4j is set higher than the dielectric constant of the second charge storing insulating film 4i, and the dielectric constant of the first insulating layer 3 and the second insulating layer 5 is set higher than the dielectric constant of the third charge storing insulating film 4j. In FIG. 11, device isolating regions, interlayer insulating films, metal wires, and the likes are omitted and are not shown. Also, the scale size in FIG. 11 is not true to the actual scale.

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

First, as shown in FIG. 12, after device isolating regions (not shown) are formed in the semiconductor substrate 1, B ions are injected with an energy of 30 keV and at a concentration of 1×10¹² atoms/cm², for example. Heat treatment is then carried out at 1050° C. for 30 seconds, for example. A first LaAlO₃ film 16 of 30 nm in thickness is formed on the semiconductor substrate 1 by CVD, for example. A Si₃N₄ film 18 of 8 nm in thickness is then formed on the first LaAlO₃ film 16 by CVD, for example.

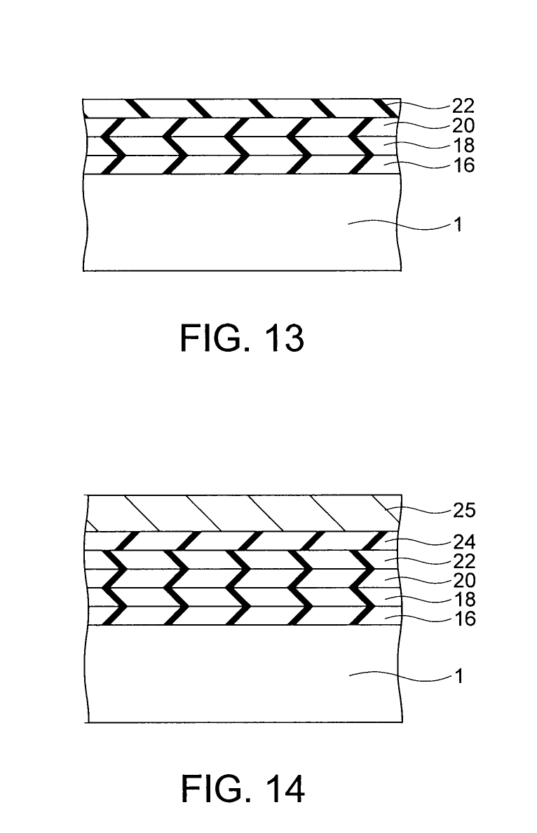

As shown in FIG. 13, an Al₂O₃ film 20 of 10 nm in thickness is then formed on the Si₃N₄ film 18 by CVD, for example. A HfO₂ film 22 of 25 nm in thickness is then formed on the Al₂O₃ film 20 by CVD, for example.

As shown in FIG. 14, a second LaAlO₃ film 24 of 30 nm in thickness is formed on the HfO₂ film 22 by CVD, for example. A W film 25 of 50 nm in thickness is then formed on the second LaAlO₃ film 24 by CVD, for example.

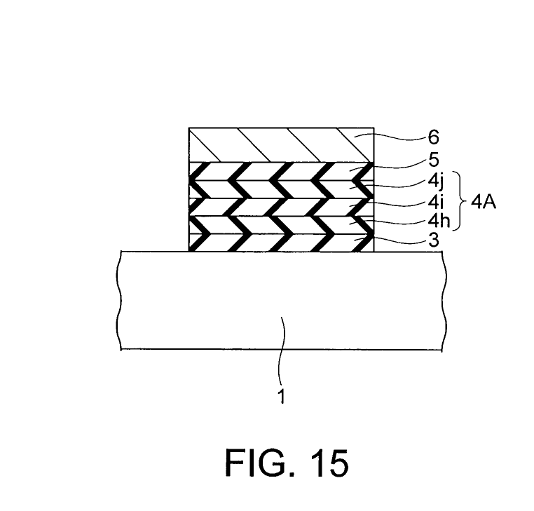

As shown in FIG. 15, patterning is then performed by RIE on the tungsten film 25, the second LaAlO₃ film 24, the HfO₂ film 22, the Al₂O₃ film 20, the Si₃N₄ film 18, and the first LaAlO₃ film 16, so as to form the control gate electrode 6, the second insulating layer 5, the third charge storing insulating film 4j, the second charge storing insulating film 4i, the first charge storing insulating film 4h, and the first insulating layer 3.

After that, As ions are injected with an energy of 5 keV and at a concentration of 1×10¹⁵ atoms/cm², for example. Heat treatment is then carried out to form the source and drain regions 2a and 2b. An interlayer insulating film forming procedure, a wiring procedure, and the likes are then carried out in the same manner as in a case where a conventional nonvolatile semiconductor memory element is manufactured by known techniques. In this manner, the nonvolatile semiconductor memory element of this embodiment shown in FIG. 11 is completed.

Normally, an interface state exists at the interface between two different materials, and charges can be stored at the interface state. Accordingly, the states existing at the interfaces in an element having the structure of this embodiment can be used in the same manner as the conductor films of the first embodiment, and the same effects as those of the first embodiment can be achieved.

Since the states existing at the interfaces between the adjacent insulating films have the same functions as the conductor films of the first embodiment, the number of films in the stacked structure forming the charge accumulating layer 4A becomes smaller, and the manufacturing procedures are simplified in this embodiment. Also, as the states existing at the interfaces between the adjacent insulating films are used as the conductor films, the length of the stacked structure consisting of the first insulating layer 3, the charge accumulating layer 4A, the second insulating layer 5, and the control gate electrode 6 becomes smaller when measured in the direction perpendicular to the substrate surface. Accordingly, formation of electrostatic capacitance is prevented between the element and any another element. As a result, a malfunction due to electrostatic capacitance formed between the element and any other element can be prevented.

Meanwhile, with the conductor films formed between the adjacent insulating films, the amount of charges to be stored in each conductor film can be more easily controlled in the first embodiment than in this embodiment. As a result, the control gate voltage for switching threshold voltage values can be easily controlled.

In this embodiment, a conductor film is not formed between any two adjacent insulating films, and the states existing at the interfaces are used as the conductor films of the first embodiment. However, this is not an essential aspect of the present invention, and the same effects as above can be achieved even if a conductor film is formed between two adjacent insulating films but a conductor film is not formed between other two adjacent insulating films.

It is also possible to make the changes and modifications described in the first embodiment to this embodiment, and to achieve the same effects as those of the first embodiment.

### Third Embodiment

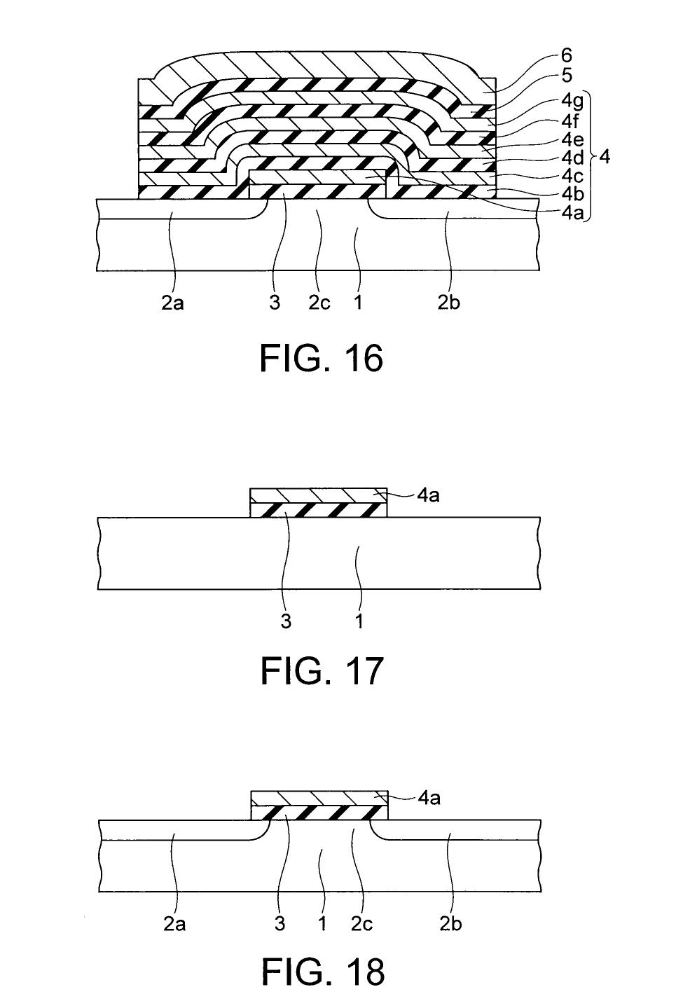

FIG. 16 is a schematic cross-sectional view of a nonvolatile semiconductor memory element in accordance with a third embodiment of the present invention.

The nonvolatile semiconductor memory element of this embodiment is the same as the nonvolatile semiconductor memory element of the first embodiment shown in FIG. 1, except that the first inter-conductor insulating film 4b has a larger film surface area than the first conductor film 4a, the second conductor film 4c has a larger film surface area than the first inter-conductor insulating layer 4b, the second inter-conductor insulating film 4d has a larger film surface area than the second conductor film 4c, the third conductor film 4e has a larger film surface area than the second inter-conductor insulating film 4d, the third inter-conductor insulating film 4f has a larger film surface area than the third conductor film 4e, the fourth conductor film 4g has a larger film surface area than the third inter-conductor insulating film 4f, the second insulating film 5 has a larger film surface area than the fourth conductor film 4g, and the control gate electrode 6 has a larger film surface area than the second insulating layer 5. The first inter-conductor insulating film 4b is formed to cover the first conductor film 4a, the second conductor film 4c is formed to cover the first inter-conductor insulating film 4b, the second inter-conductor insulating film 4d is formed to cover the second conductor film 4c, the third conductor film 4e is formed to cover the second inter-conductor insulating film 4d, the third inter-conductor insulating film 4f is formed to cover the third conductor film 4e, the fourth conductor film 4g is formed to cover the third inter-conductor insulating film 4f, the second insulating layer 5 is formed to cover the fourth conductor film 4g, and the control gate electrode 6 is formed to cover the second insulating layer 5. In FIG. 16, device isolating regions, interlayer insulating films, metal wires, and the likes are omitted and are not shown. Also, the scale size in FIG. 16 is not true to the actual scale.

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

First, the same procedure as that illustrated in FIG. 5 is carried out. After that, the procedure illustrated in FIG. 17 is carried out. More specifically, patterning is performed on the first polycrystalline silicon film 17 and the first LaAlO₃ film 16 by RIE or the like, so as to form the first conductor film 4a and the first insulating layer 3.

As shown in FIG. 18, As ions are injected with an energy of 5 keV and at a concentration of 1×10¹⁵ atoms/cm², for example. Heat treatment is then carried out to form the source and drain regions 2a and 2b. Here, the region 2c of the semiconductor substrate 1 located between the source region 2a and the drain region 2b becomes the channel.

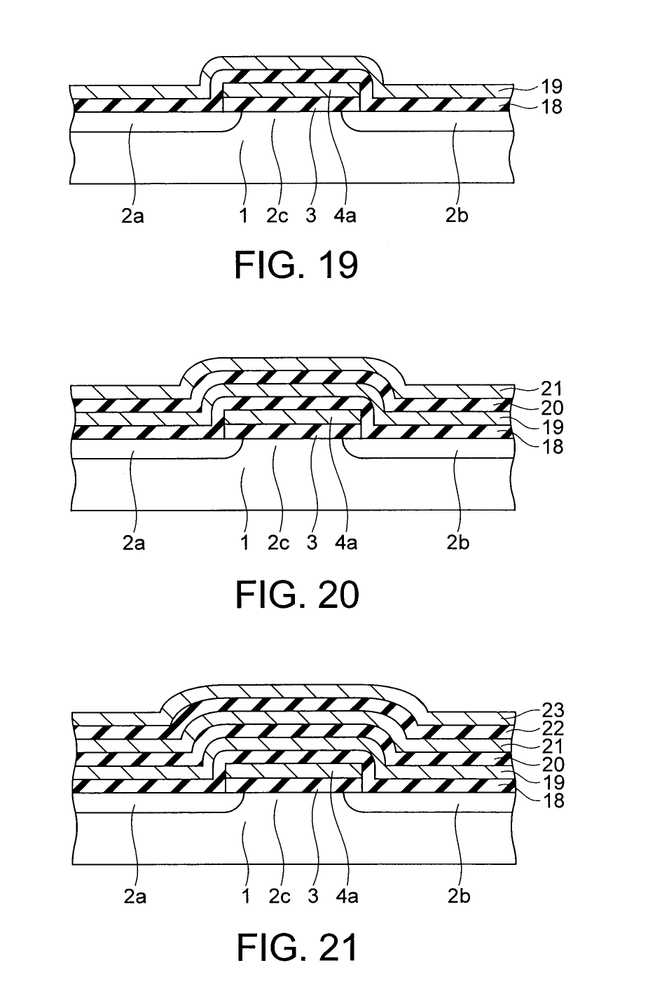

As shown in FIG. 19, a Si₃N₄ film 18 of 8 nm in thickness is then formed on the entire surface of the semiconductor substrate 1 including the first insulating layer 3 and the first conductor film 4a by CVD, for example. A 5-nm thick second polycrystalline silicon film 19 containing As or the like at a concentration of 2×10¹⁸ atoms/cm³ is then formed on the Si₃N₄ film 18 by CVD, for example.

As shown in FIG. 20, an Al₂O₃ film 20 of 10 nm in thickness is then formed on the second polycrystalline silicon film 19 by CVD, for example. A 5-nm thick third polycrystalline silicon film 21 containing As or the like at a concentration of 2×10¹⁸ atoms/cm³ is then formed on the Al₂O₃ film 20 by CVD, for example.

As shown in FIG. 21, a HfO₂ film 22 of 25 nm in thickness is then formed on the third polycrystalline silicon film 21 by CVD, for example. A 5-nm thick fourth polycrystalline silicon film 23 containing As or the like at a concentration of 2×10¹⁸ atoms/cm³ is then formed on the HfO₂ film 22 by CVD, for example.

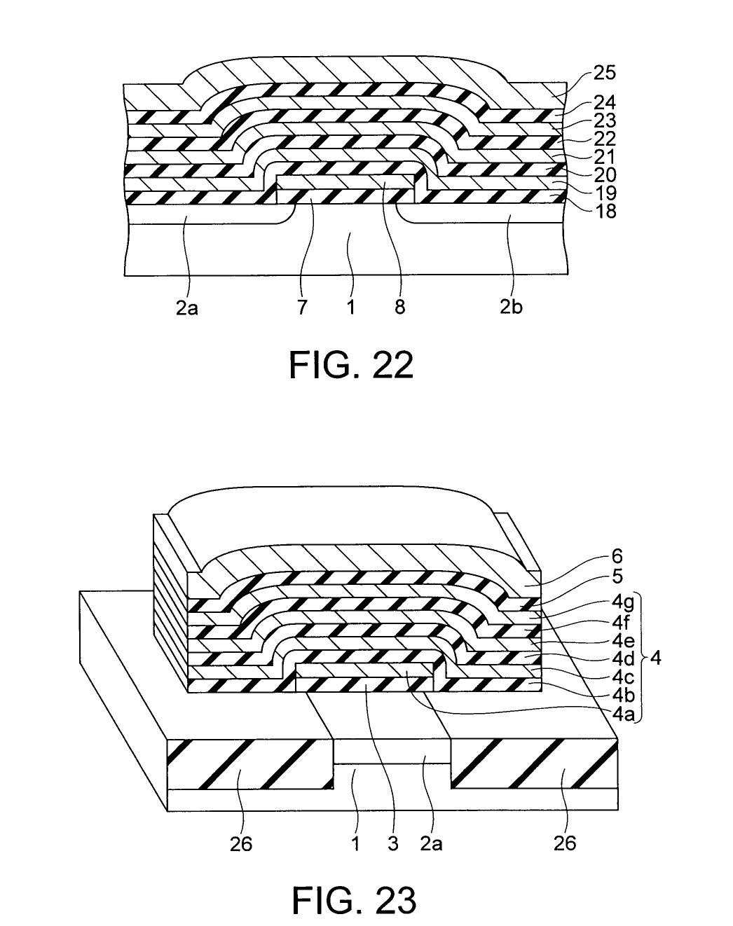

As shown in FIG. 22, a second LaAlO₃ film 24 of 30 nm in thickness is formed on the fourth polycrystalline silicon film 23 by CVD, for example. A W film 25 of 50 nm in thickness is then formed on the second LaAlO₃ film 24 by CVD, for example.

Patterning is then performed by RIE or the like on the stacked films consisting of the tungsten film 25, the second LaAlO₃ film 24, the fourth polycrystalline silicon film 23, the HfO₂ film 22, the third polycrystalline silicon film 21, the Al₂O₃ film 20, the second polycrystalline silicon film 19, and the Si₃N₄ film 18, so as to form the control gate electrode 6, the second insulating layer 5, the fourth conductor film 4g, the third inter-conductor insulating film 4f, the third conductor film 4e, the second inter-conductor insulating film 4d, the second conductor film 4c, and the first inter-conductor insulating film 4b. After that, an interlayer insulating film forming procedure, a wiring procedure, and the likes are carried out in the same manner as in a case where a conventional nonvolatile semiconductor memory element is manufactured by known techniques. In this manner, the nonvolatile semiconductor memory element of this embodiment shown in FIG. 16 is completed.

In the nonvolatile semiconductor memory element of this embodiment, the first inter-conductor insulating film 4b is formed to cover the first conductor film 4a, the second conductor film 4c is formed to cover the first inter-conductor insulating film 4b, the second inter-conductor insulating film 4d is formed to cover the second conductor film 4c, the third conductor film 4e is formed to cover the second inter-conductor insulating film 4d, the third inter-conductor insulating film 4f is formed to cover the third conductor film 4e, the fourth conductor film 4g is formed to cover the third inter-conductor insulating film 4f, the second insulating layer 5 is formed to cover the fourth conductor film 4g, and the control gate electrode 6 is formed to cover the second insulating layer 5, as described above. With this arrangement, the electric fields Eᵢₙₜ₁, Eᵢₙₜ₂ and Eᵢₙₜ₃ in the first to third inter-conductor insulating films 4b, 4d, and 4f have the relationship Eᵢₙₜ₁>Eᵢₙₜ₂>Eᵢₙₜ₃, even if the first to third inter-conductor insulating films 4b, 4d, and 4f have the same dielectric constants. Accordingly, as the control gate voltage V_{CG} increases, the threshold voltage V_{TH} varies in a stepwise manner, as described in the first embodiment. However, when the first to third inter-conductor insulating films 4b, 4d, and 4f have the same dielectric constants, the difference between the electric field Eᵢₙₜ₂ and the electric field Eᵢₙₜ₃ is smaller than the difference between the electric field Eᵢₙₜ₁ and the electric field Eᵢₙₜ₂. Therefore, when the first to third inter-conductor insulating films 4b, 4d, and 4f have the same dielectric constants, the difference between V₂′ and V₃ is smaller than the difference between V₁′ and V₂, as indicated by broken lines in FIG. 4. Here, V₁, V₁′, and V₂ are shown in FIG. 4 and are hypothetically the same as those in the first embodiment, for ease of explanation.

As described above in this embodiment, the first inter-conductor insulating film 4b is formed to cover the first conductor film 4a, the second conductor film 4c is formed to cover the first inter-conductor insulating film 4b, the second inter-conductor insulating film 4d is formed to cover the second conductor film 4c, the third conductor film 4e is formed to cover the second inter-conductor insulating film 4d, the third inter-conductor insulating film 4f is formed to cover the third conductor film 4e, the fourth conductor film 4g is formed to cover the third inter-conductor insulating film 4f, the second insulating layer 5 is formed to cover the fourth conductor film 4g, and the control gate electrode 6 is formed to cover the second insulating layer 5. When the dielectric constants of the first to third inter-conductor insulating films 4b, 4d, and 4f satisfy the relationships kᵢₙₜ₁<kᵢₙₜ₂<kᵢₙₜ₃, the inequation Eᵢₙₜ₁>Eᵢₙₜ₂>Eᵢₙₜ₃ is more effectively realized with those dielectric constants. As a result, the difference between V₁′ and V₂ and the difference between V₂′ and V₃ indicated by a dot-and-dash line in FIG. 4 become larger than those in the nonvolatile semiconductor memory element of the first embodiment. In this manner, it is possible to allow greater margins in the operating voltage.

In the case where the first inter-conductor insulating film 4b is formed to cover the first conductor film 4a, the second conductor film 4c is formed to cover the first inter-conductor insulating film 4b, the second inter-conductor insulating film 4d is formed to cover the second conductor film 4c, the third conductor film 4e is formed to cover the second inter-conductor insulating film 4d, the third inter-conductor insulating film 4f is formed to cover the third conductor film 4e, the fourth conductor film 4g is formed to cover the third inter-conductor insulating film 4f, the second insulating layer 5 is formed to cover the fourth conductor film 4g, and the control gate electrode 6 is formed to cover the second insulating layer 5, it is possible to set the dielectric constants of the first to third inter-conductor insulating films 4b, 4d, and 4f at the same value. Accordingly, the first to third inter-conductor insulating films 4b, 4d, and 4f do not need to be made of different materials from one another, and a higher degree of freedom can be allowed in selecting the materials for those inter-conductor insulating films.

On the other hand, to manufacture a nonvolatile semiconductor memory element having the structure of the first embodiment, it is possible to form the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, and the first insulating layer 3 in one procedure. Accordingly, the first embodiment has the advantage that the manufacturing procedures are simplified.

In the nonvolatile semiconductor memory element of this embodiment, the first inter-conductor insulating film 4b is longer than the first conductor film 4a in the principal direction of the current flowing in the channel region (the channel length direction), the second conductor film 4c is longer than the first inter-conductor insulating film 4b in the principal direction of the current flowing in the channel region, the second inter-conductor insulating film 4d is longer than the second conductor film 4c in the principal direction of the current flowing in the channel region, the third conductor film 4e is longer than the second inter-conductor insulating film 4d in the principal direction of the current flowing in the channel region, the third inter-conductor insulating film 4f is longer than the third conductor film 4e in the principal direction of the current flowing in the channel region, the fourth conductor film 4g is longer than the third inter-conductor insulating film 4f in the principal direction of the current flowing in the channel region, the second insulating layer 5 is longer than the fourth conductor film 4g in the principal direction of the current flowing in the channel region, and the control gate electrode 6 is longer than the second insulating layer 5 in the principal direction of the current flowing in the channel region.

In a modification of this embodiment shown in FIG. 23, on the other hand, the first inter-conductor insulating film 4b is longer than the first conductor film 4a in the direction perpendicular to the principal direction of the current flowing in the channel region (the channel width direction), the second conductor film 4c is longer than the first inter-conductor insulating film 4b in the direction perpendicular to the principal direction of the current flowing in the channel region, the second inter-conductor insulating film 4d is longer than the second conductor film 4c in the direction perpendicular to the principal direction of the current flowing in the channel region, the third conductor film 4e is longer than the second inter-conductor insulating film 4d in the direction perpendicular to the principal direction of the current flowing in the channel region, the third inter-conductor insulating film 4f is longer than the third conductor film 4e in the direction perpendicular to the principal direction of the current flowing in the channel region, the fourth conductor film 4g is longer than the third inter-conductor insulating film 4f in the direction perpendicular to the principal direction of the current flowing in the channel region, the second insulating layer 5 is longer than the fourth conductor film 4g in the direction perpendicular to the principal direction of the current flowing in the channel region, and the control gate electrode 6 is longer than the second insulating layer 5 in the direction perpendicular to the principal direction of the current flowing in the channel region. In FIG. 23, reference numeral 26 indicates the device isolating regions. One of the source and drain regions 2a and 2b (the source region 2a in the example shown in FIG. 23) is located on the front side of the stacked films including the first insulating layer 3 to the control gate electrode 6, and the other one (the drain region 2b) is located on the opposite side, though not shown in FIG. 23, being behind the stacked films. In this modification, the length of the first insulating layer 3 and the first conductor film 4a in the channel width direction is made greater than the channel width, so that the first insulating layer 3 and the first conductor film 4a extend onto the device isolating regions 26. In FIG. 23, interlayer insulating films, metal wires, and the likes are omitted and are not shown. Also, the scale size in FIG. 23 is not true to the actual scale. Unlike the nonvolatile semiconductor memory element of this embodiment, the nonvolatile semiconductor memory element of this modification has a reduced capacitance formed at the overlapping portions between the second conductor film 4c and the source and drain regions 2a and 2b. Accordingly, the parasitic capacitance is reduced, and the operating speed of the element can be increased.

In this embodiment on the other hand, the length of the control gate electrode 6 measured in the principal direction of the current flowing in the channel is greater. Accordingly, the gate resistance is reduced and the operating speed of the element can be increased.

It is also possible to make the changes and modifications described in the first embodiment to this embodiment, and to achieve the same effects as those of the first embodiment.

### Fourth Embodiment

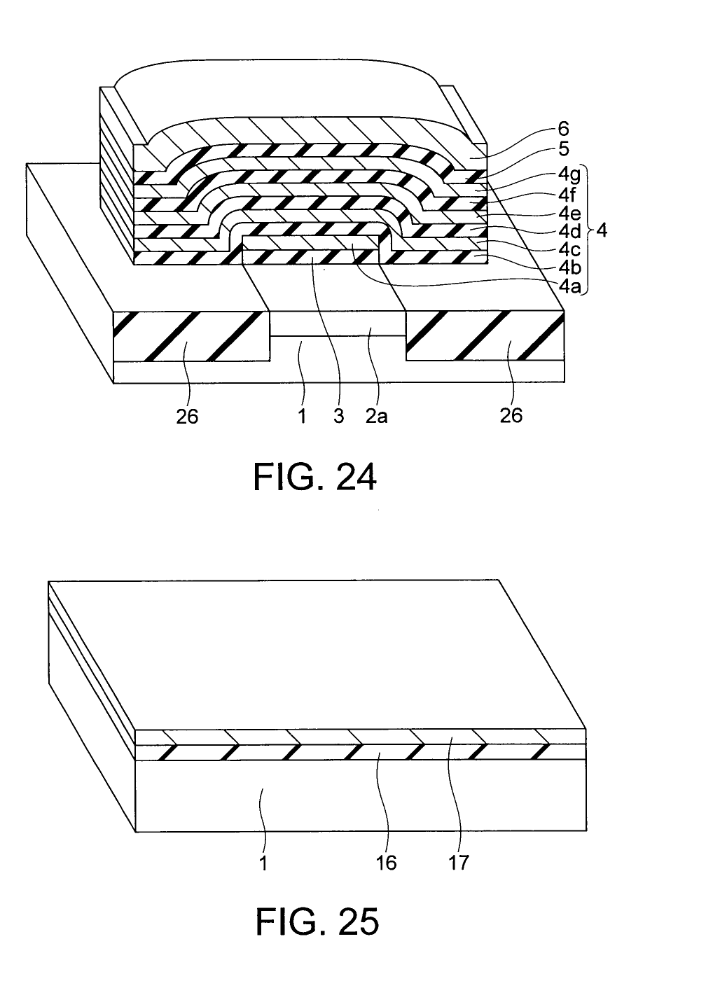

FIG. 24 shows a nonvolatile semiconductor memory element in accordance with a fourth embodiment of the present invention. The nonvolatile semiconductor memory element of this embodiment is the same as the nonvolatile semiconductor memory element of the modification of the third embodiment shown in FIG. 23, except that the device isolating regions 26, the first insulating layer 3, and the first conductor film 4a are formed in a self-aligning manner. In FIG. 24, interlayer insulating films, metal wires, and the likes are omitted and are not shown. Also, the scale size in FIG. 24 is not true to the actual scale.

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

First, as shown in FIG. 25, B ions are injected into the semiconductor substrate 1 with an energy of 30 keV and at a concentration of 1×10¹² atoms/cm², for example. Heat treatment is then carried out at 1050° C. for 30 seconds, for example. A first LaAlO₃ film 16 of 30 nm in thickness is formed on the semiconductor substrate 1 by CVD, for example. A 5-nm thick first polycrystalline silicon film 17 containing As or the like at a concentration of 2×10¹⁸ atoms/cm³ is then formed on the first LaAlO₃ film 16 by CVD, for example.

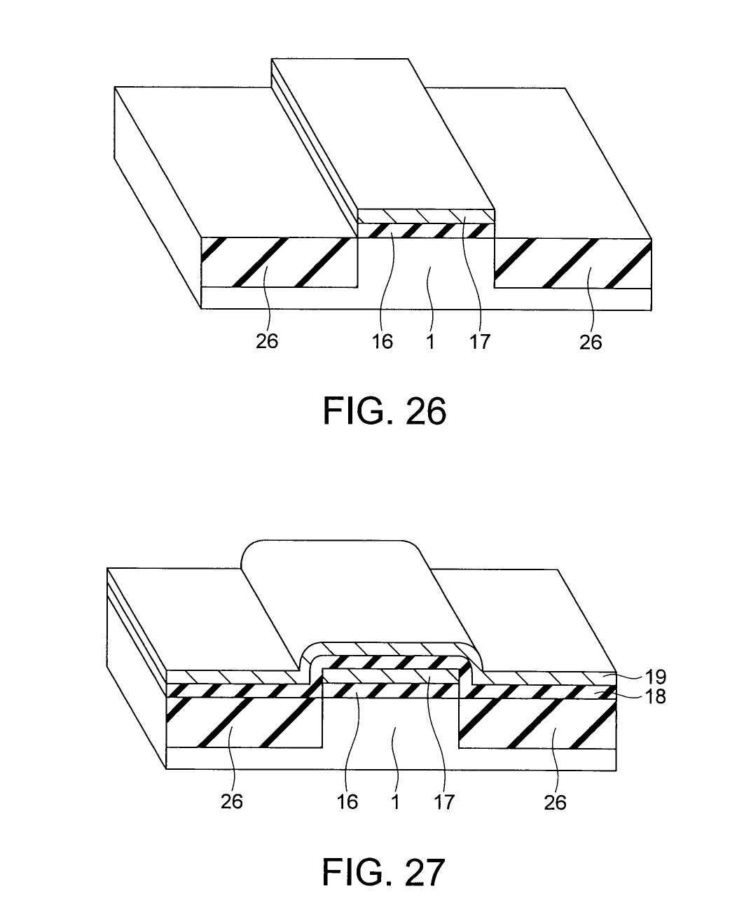

As shown in FIG. 26, a mask (not shown) is formed on the first polycrystalline silicon film 17, and patterning is performed on the first polycrystalline silicon film 17 and the first LaAlO₃ film 16 by RIE, for example. With the use of the mask, grooves are formed in the semiconductor substrate 1, and the grooves are filled with an insulating material such as silicon oxide, so as to form the device isolating regions 26. After that, the mask is removed.

As shown in FIG. 27, a Si₃N₄ film 18 of 8 nm in thickness is then formed on the entire surface of the semiconductor substrate 1 including the first LaAlO₃ film 16 and the first polycrystalline silicon film 17 by CVD, for example. A 5-nm thick second polycrystalline silicon film 19 containing As or the like at a concentration of 2×10¹⁸ atoms/cm³ is then formed on the Si₃N₄ film 18 by CVD, for example.

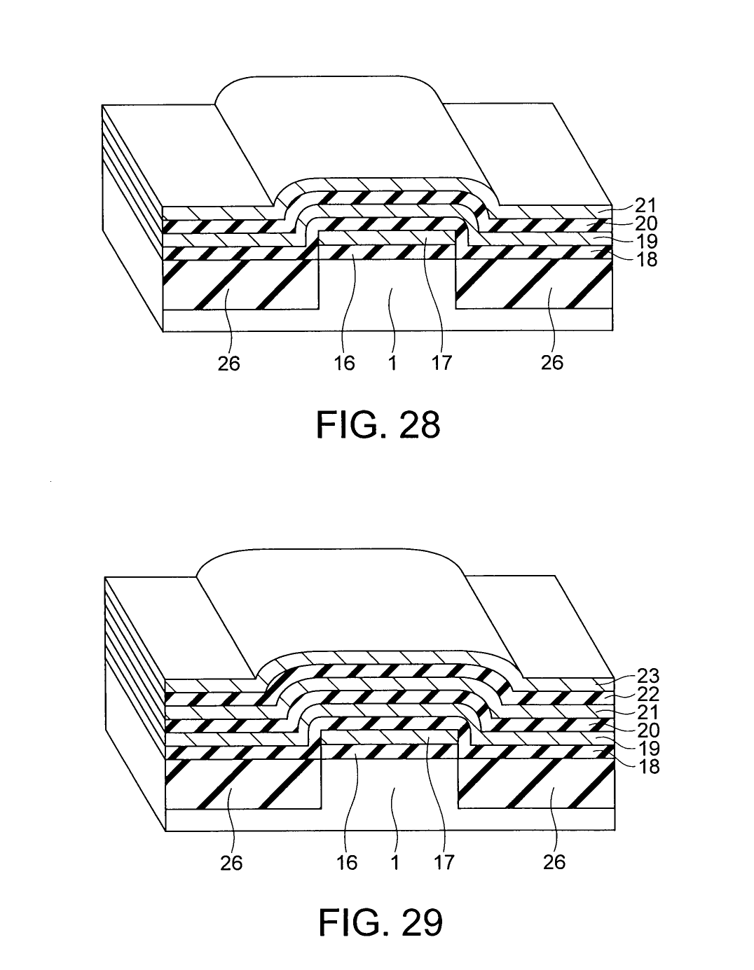

As shown in FIG. 28, an Al₂O₃ film 20 of 10 nm in thickness is then formed on the second polycrystalline silicon film 19 by CVD, for example. A 5-nm thick third polycrystalline silicon film 21 containing As or the like at a concentration of 2×10¹⁸ atoms/cm³ is then formed on the Al₂O₃ film 20 by CVD, for example.

As shown in FIG. 29, a HfO₂ film 22 of 25 nm in thickness is then formed on the third polycrystalline silicon film 21 by CVD, for example. A 5-nm thick fourth polycrystalline silicon film 23 containing As or the like at a concentration of 2×10¹⁸ atoms/cm³ is then formed on the HfO₂ film 22 by CVD, for example.

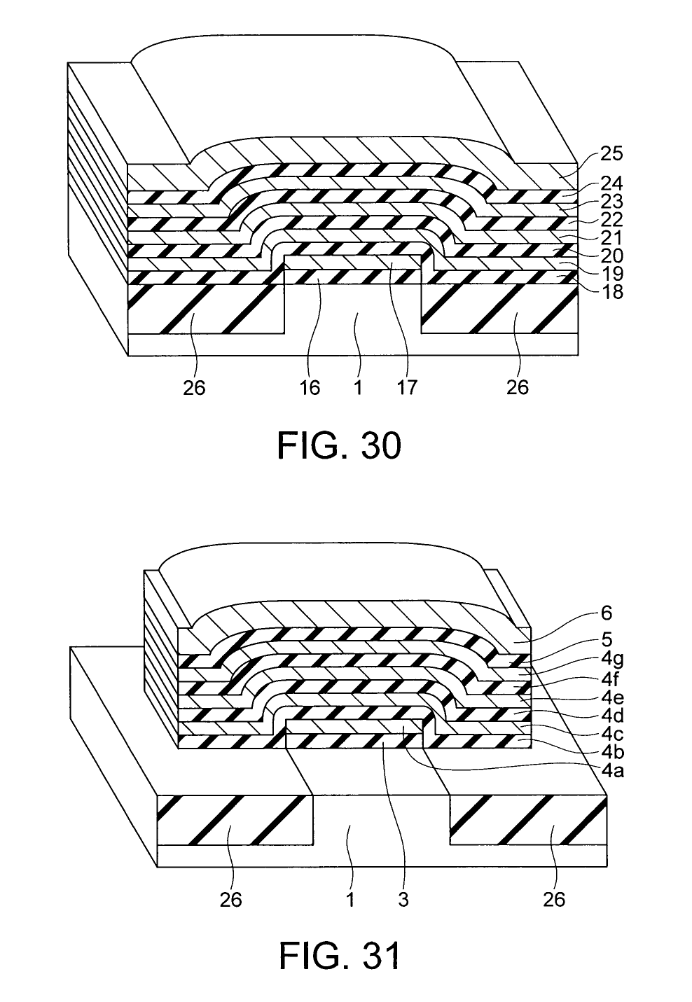

As shown in FIG. 30, a second LaAlO₃ film 24 of 30 nm in thickness is formed on the fourth polycrystalline silicon film 23 by CVD, for example. A W film 25 of 50 nm in thickness is then formed on the second LaAlO₃ film 24 by CVD, for example.

As shown in FIG. 31, patterning is then performed by RIE or the like on the tungsten film 25, the second LaAlO₃ film 24, the fourth polycrystalline silicon film 23, the HfO₂ film 22, the third polycrystalline silicon film 21, the Al₂O₃ film 20, the second polycrystalline silicon film 19, the Si₃N₄ film 18, the first polycrystalline silicon film 17, and the first LaAlO₃ film 16, so as to form the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, and the first insulating layer 3.

After that, As ions are injected with an energy of 5 keV and at a concentration of 1×10¹⁵ atoms/cm², for example. Heat treatment is then carried out to form the source and drain regions 2a and 2b. An interlayer insulating film forming procedure, a wiring procedure, and the likes are then carried out in the same manner as in a case where a conventional nonvolatile semiconductor memory element is manufactured by known techniques. In this manner, the nonvolatile semiconductor memory element of this embodiment shown in FIG. 24 is completed.

In this embodiment, the device isolating regions 26, the first insulating layer 3, and the first conductor film 4a are formed in a self-aligning manner. Accordingly, it is possible to form the device isolating regions 26, the first insulating layer 3, and the first conductor film 4a with the use of the same mask, and the manufacturing procedures are simplified. If nonvolatile semiconductor memory elements are produced in the same manner as in any of the foregoing embodiments, on the other hand, surface flattening can be performed by a chemical mechanical polishing method (hereinafter referred to as “CMP”) after the procedure for filling the grooves with an insulating material such as silicon oxide to form the device isolating regions. As a result, the step portions between the surface of the channel region and the surfaces of the device isolating regions can be minimized.

It is also possible to make the changes and modifications described in the foregoing embodiments to this embodiment, and to achieve the same effects as those of the foregoing embodiments.

### Fifth Embodiment

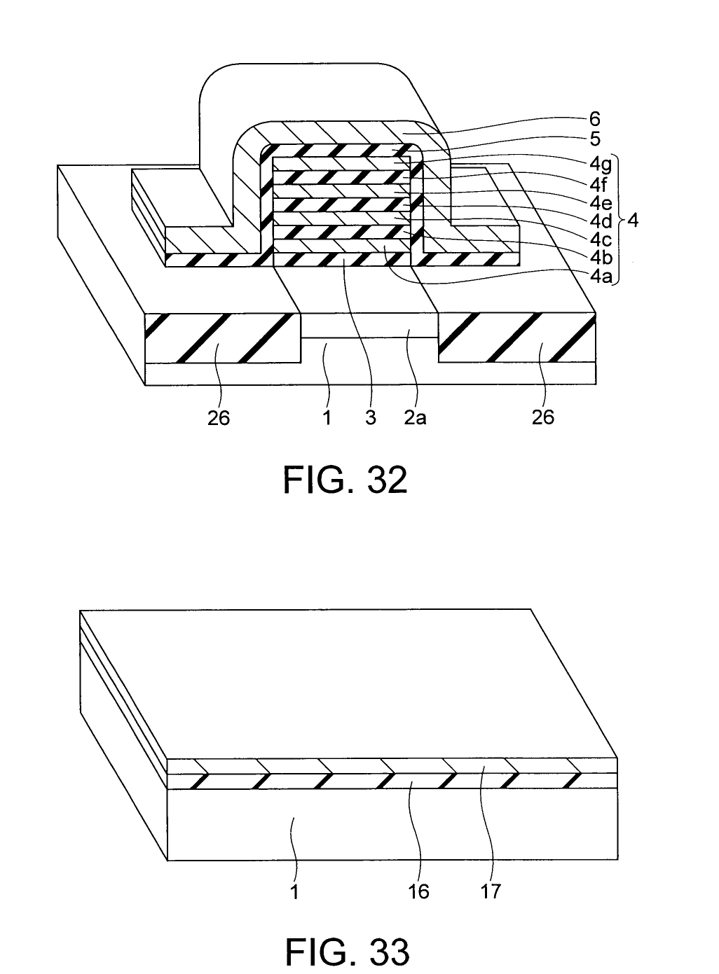

FIG. 32 shows a nonvolatile semiconductor memory element in accordance with a fifth embodiment of the present invention. The nonvolatile semiconductor memory element of this embodiment is the same as the nonvolatile semiconductor memory element of the modification of the third embodiment shown in FIG. 23, except that the device isolating regions 26 and the stacked structure consisting of the first insulating layer 3 and the charge accumulating layer 4 are formed in a self-aligning manner. In FIG. 32, interlayer insulating films, metal wires, and the likes are omitted and are not shown. Also, the scale size in FIG. 32 is not true to the actual scale.

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

First, as shown in FIG. 33, B ions are injected into the semiconductor substrate 1 with an energy of 30 keV and at a concentration of 1×10¹² atoms/cm², for example. Heat treatment is then carried out at 1050° C. for 30 seconds, for example. A first LaAlO₃ film 16 of 30 nm in thickness is formed on the semiconductor substrate 1 by CVD, for example. A 5-nm thick first polycrystalline silicon film 17 containing As or the like at a concentration of 2×10¹⁸ atoms/cm³ is then formed on the first LaAlO₃ film 16 by CVD, for example.

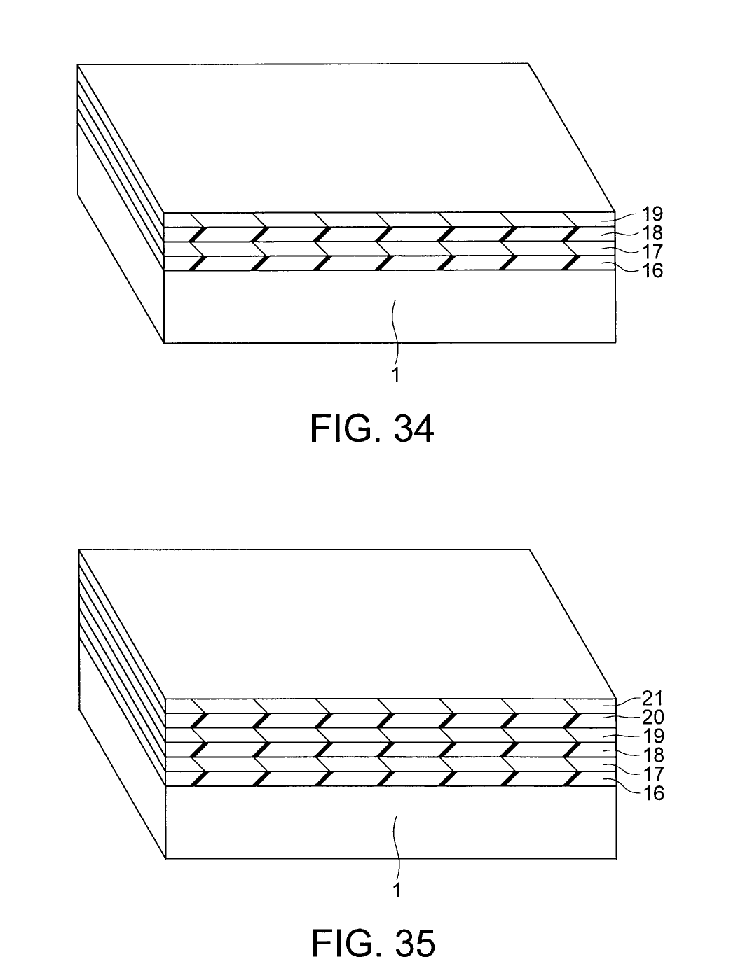

As shown in FIG. 34, a Si₃N₄ film 18 of 8 nm in thickness is then formed on the first polycrystalline silicon film 17 by CVD, for example. A 5-nm thick second polycrystalline silicon film 19 containing As or the like at a concentration of 2×10¹⁸ atoms/cm³ is then formed on the Si₃N₄ film 18 by CVD, for example.

As shown in FIG. 35, an Al₂O₃ film 20 of 10 nm in thickness is then formed on the second polycrystalline silicon film 19 by CVD, for example. A 5-nm thick third polycrystalline silicon film 21 containing As or the like at a concentration of 2×10¹⁸ atoms/cm³ is then formed on the Al₂O₃ film 20 by CVD, for example.

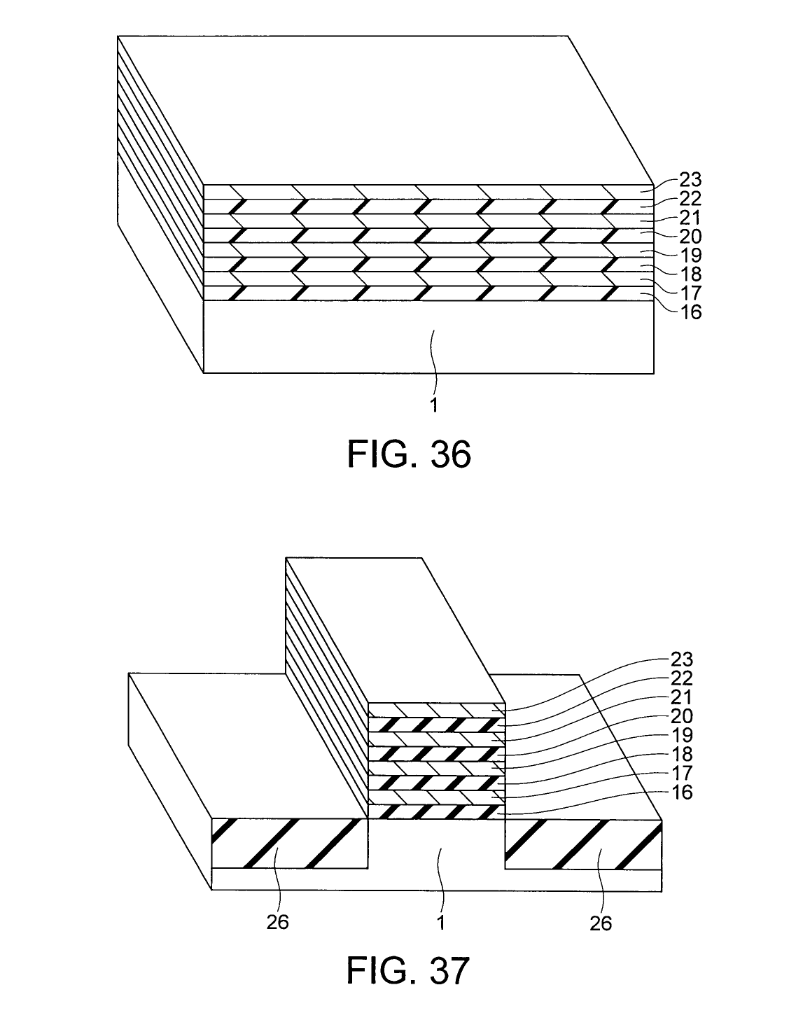

As shown in FIG. 36, a HfO₂ film 22 of 25 nm in thickness is then formed on the third polycrystalline silicon film 21 by CVD, for example. A 5-nm thick fourth polycrystalline silicon film 23 containing As or the like at a concentration of 2×10¹⁸ atoms/cm³ is then formed on the HfO₂ film 22 by CVD, for example.

As shown in FIG. 37, patterning is performed by RIE on the fourth polycrystalline silicon film 23, the HfO₂ film 22, the third polycrystalline silicon film 21, the Al₂O₃ film 20, the second polycrystalline silicon film 19, the Si₃N₄ film 18, the first polycrystalline silicon film 17, and the first LaAlO₃ film 16. Grooves are then formed in the semiconductor substrate 1, and the grooves are filled with an insulating material such as silicon oxide, so as to form the device isolating regions 26.

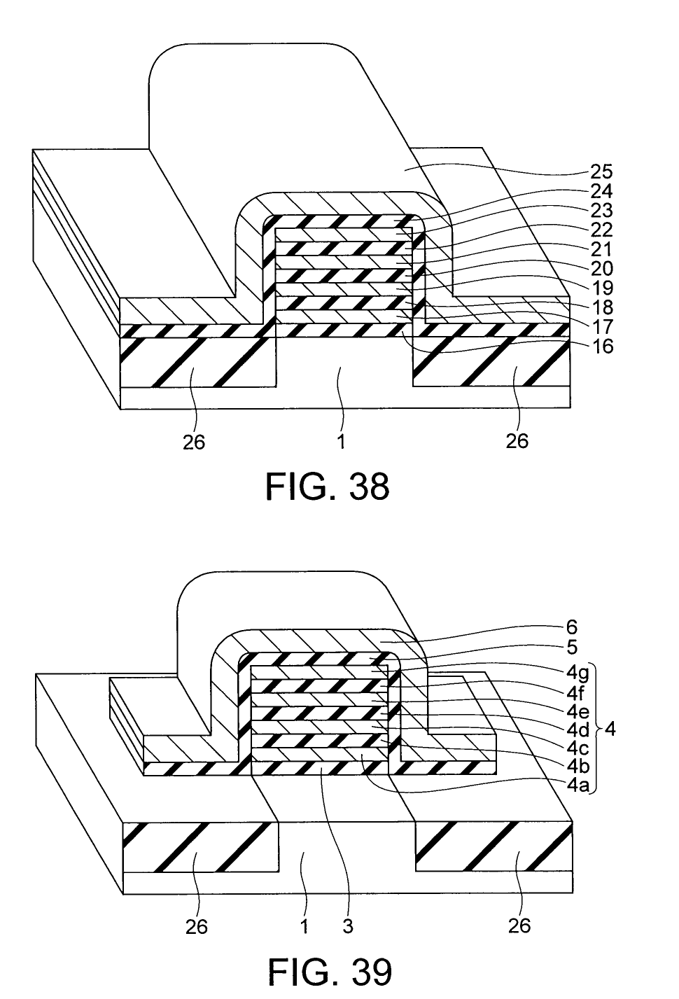

As shown in FIG. 38, a second LaAlO₃ film 24 of 30 nm in thickness is formed by CVD on the entire surface of the semiconductor substrate 1 including the first LaAlO₃ film 16, the first polycrystalline silicon film 17, the Si₃N₄ film 18, the second polycrystalline silicon film 19, the Al₂O₃ film 20, the third polycrystalline silicon film 21, the HfO₂ film 22, and the fourth polycrystalline silicon film 23, for example. A W film 25 of 50 nm in thickness is then formed on the second LaAlO₃ film 24 by CVD, for example.

As shown in FIG. 39, patterning is then performed by RIE or the like on the tungsten film 25, the second LaAlO₃ film 24, the fourth polycrystalline silicon film 23, the HfO₂ film 22, the third polycrystalline silicon film 21, the Al₂O₃ film 20, the second polycrystalline silicon film 19, the Si₃N₄ film 18, the first polycrystalline silicon film 17, and the first LaAlO₃ film 16, so as to form the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, and the first insulating layer 3. The charge accumulating layer 4 is formed with the first conductor film 4a, the first inter-conductor insulating film 4b, the second conductor film 4c, the second inter-conductor insulating film 4d, the third conductor film 4e, the third inter-conductor insulating film 4f, and the fourth conductor film 4g.

After that, As ions are injected with an energy of 5 keV and at a concentration of 1×10¹⁵ atoms/cm², for example. Heat treatment is then carried out to form the source and drain regions 2a and 2b. An interlayer insulating film forming procedure, a wiring procedure, and the likes are then carried out in the same manner as in a case where a conventional nonvolatile semiconductor memory element is manufactured by known techniques. In this manner, the nonvolatile semiconductor memory element of this embodiment shown in FIG. 32 is completed.

In a nonvolatile semiconductor memory element having the structure of this embodiment, the device isolating regions 26 and the stacked structure consisting of the first insulating layer 3 and the charge accumulating layer 4 are formed in a self-aligning manner. Accordingly, it is possible to form the device isolating regions 26, the first insulating layer 3, and the charge accumulating layer 4 with the use of the same mask, and the manufacturing procedures are simplified. If nonvolatile semiconductor memory elements each having the structure of this embodiment are manufactured, the elements can be formed in the cycle twice as large as the minimum processing size in directions both parallel and perpendicular to the principal direction of the current flowing in the channel. Accordingly, the area of each one element can be made four times as large as the square of the minimum processing size. As a result, high integration can be realized. If nonvolatile semiconductor memory elements are produced in the same manner as in any of the first to third embodiments, on the other hand, surface flattening can be performed by CMP after the procedure for filling the grooves with an insulating material such as silicon oxide to form the device isolating regions. As a result, the step portions between the surface of the channel region and the surfaces of the device isolating regions can be minimized.

It is also possible to make the changes and modifications described in the foregoing embodiments to this embodiment, and to achieve the same effects as those of the foregoing embodiments.

### Sixth Embodiment

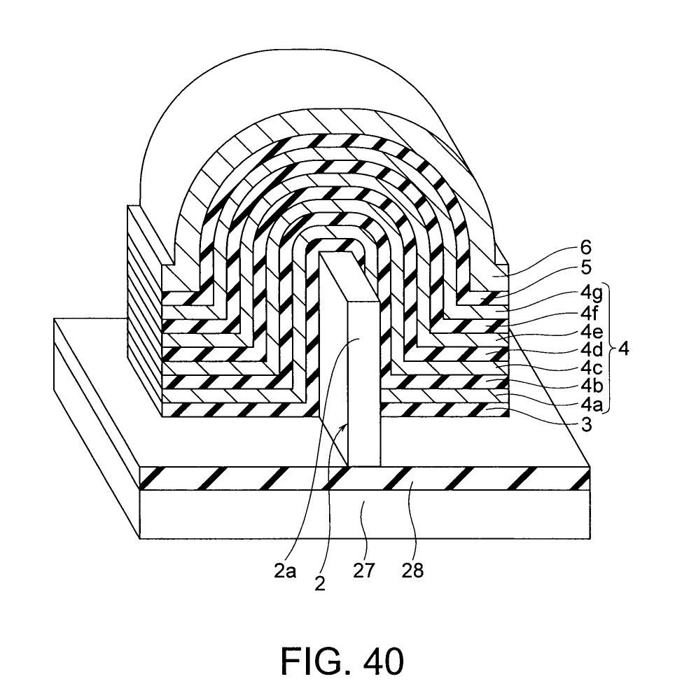

FIG. 40 shows a nonvolatile semiconductor memory element in accordance with a sixth embodiment of the present invention. The nonvolatile semiconductor memory element of this embodiment differs from any of the nonvolatile semiconductor memory elements of the foregoing embodiments, in that it is formed on a so-called SOI substrate having a semiconductor layer formed above a supporting substrate 27 to sandwich an embedded insulating film 28, the semiconductor layer on the embedded insulating film 28 has a plate-like shape, and source and drain regions are formed at a distance from each other in the longitudinal direction of a plate-like semiconductor region 2. A first insulating layer 3, a charge accumulating layer 4, a second insulating layer 5, and a control gate electrode 6 are formed to cover the plate-like semiconductor region 2 between the source region and the drain region. The charge accumulating layer 4 has a stacked structure formed by stacking a first conductor film 4a, a first inter-conductor insulating film 4b, a second conductor film 4c, a second inter-conductor insulating film 4d, a third conductor film 4e, a third inter-conductor insulating film 4f, and a fourth conductor film 4g. One of the source and drain regions is located on the front side of the stacked structure consisting of the first insulating layer 3, the charge accumulating layer 4, the second insulating layer 5, and the control gate electrode 6, and the other one is located on the opposite side of the stacked structure, though not shown in FIG. 40, being behind the stacked films. In FIG. 40, device isolating regions, interlayer insulating films, metal wires, and the likes are omitted and are not shown. Also, the scale size in FIG. 40 is not true to the actual scale.

A method for manufacturing a nonvolatile semiconductor memory element in accordance with this embodiment is now described. In the following, a case of an n-type nonvolatile semiconductor memory element is described. It should be noted that a p-type nonvolatile semiconductor memory element can be manufactured in the same manner as described below, if the conductivity types of the impurities are reversed from those in an n-type nonvolatile semiconductor memory element.

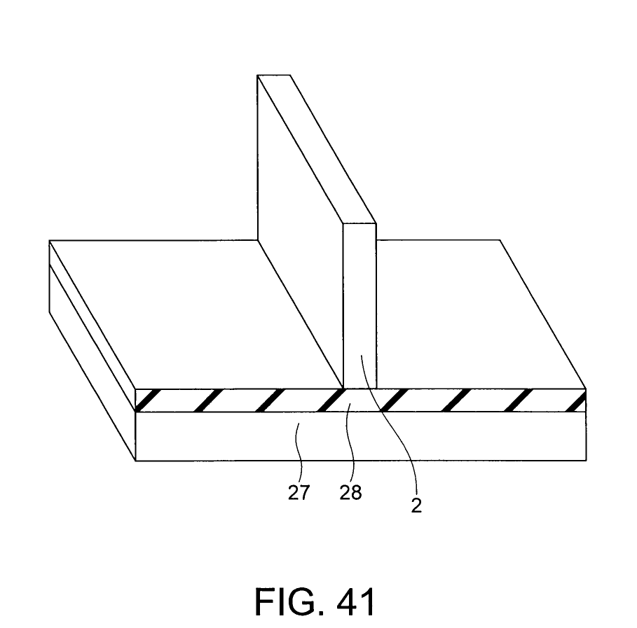

First, as shown in FIG. 41, B ions are injected into the semiconductor layer on the SOI substrate with an energy of 30 keV and at a concentration of 1×10¹² atoms/cm², for example. Heat treatment is then carried out at 1050° C. for 30 seconds, for example. The semiconductor layer is then processed by RIE or the like, so as to form the plate-like semiconductor region 2.

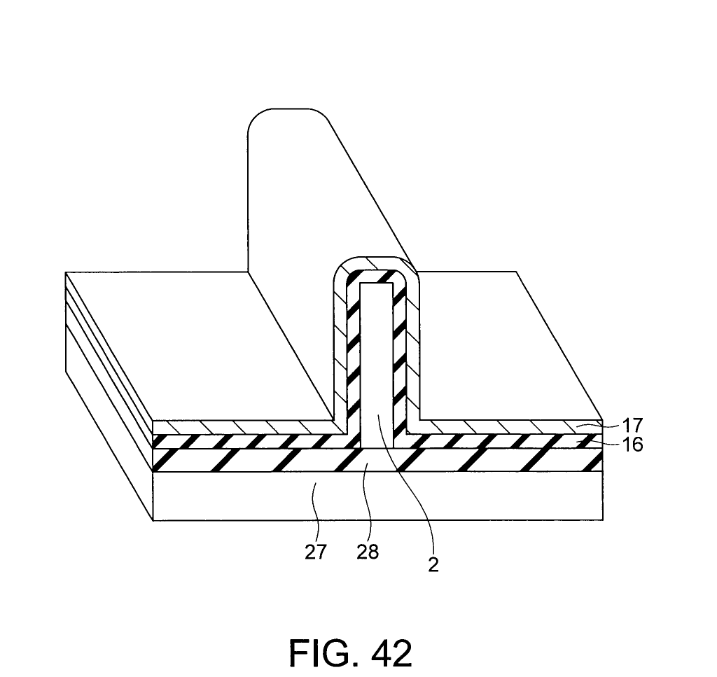

As shown in FIG. 42, a first LaAlO₃ film 16 of 30 nm in thickness is formed on the entire surface of the SOI substrate including the plate-like semiconductor region 2 by CVD, for example. A 5-nm thick first polycrystalline silicon film 17 containing As or the like at a concentration of 2×10¹⁸ atoms/cm³ is then formed on the first LaAlO₃ film 16 by CVD, for example.

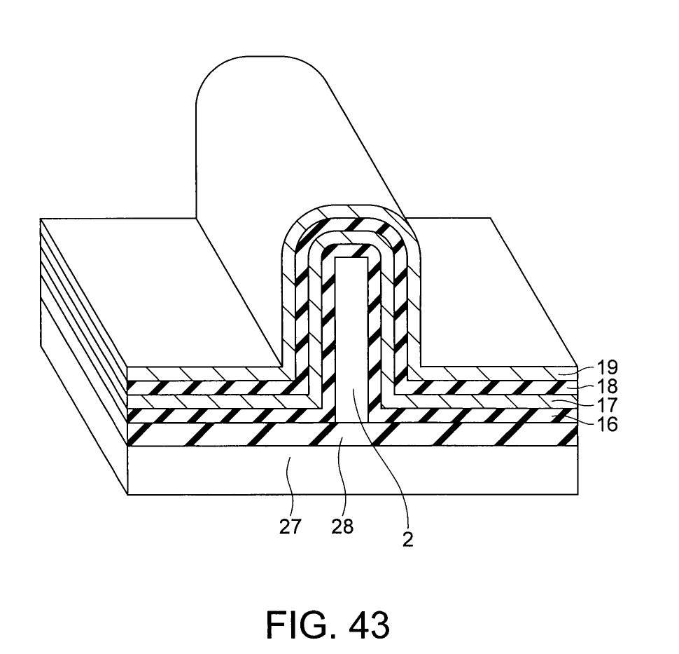

As shown in FIG. 43, a Si₃N₄ film 18 of 8 nm in thickness is then formed on the first polycrystalline silicon film 17 by CVD, for example. A 5-nm thick second polycrystalline silicon film 19 containing As or the like at a concentration of 2×10¹⁸ atoms/cm³ is then formed on the Si₃N₄ film 18 by CVD, for example.

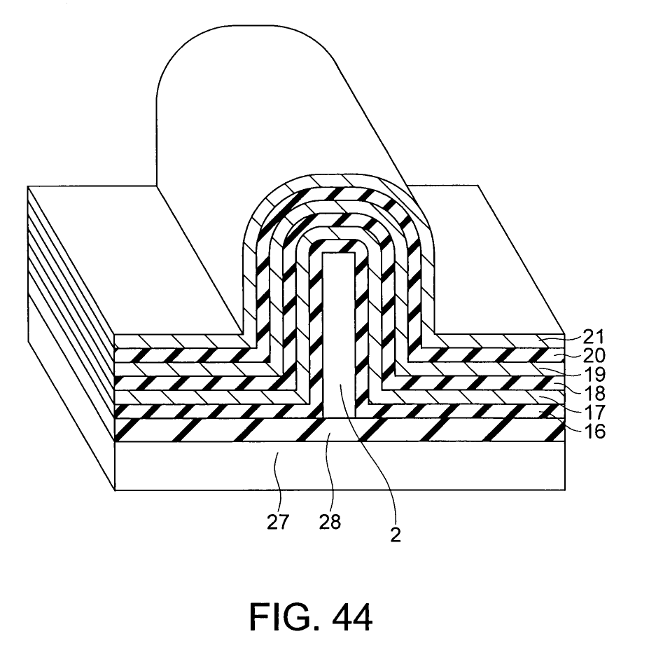

As shown in FIG. 44, an Al₂O₃ film 20 of 10 nm in thickness is then formed on the second polycrystalline silicon film 19 by CVD, for example. A 5-nm thick third polycrystalline silicon film 21 containing As or the like at a concentration of 2×10¹⁸ atoms/cm³ is then formed on the Al₂O₃ film 20 by CVD, for example.

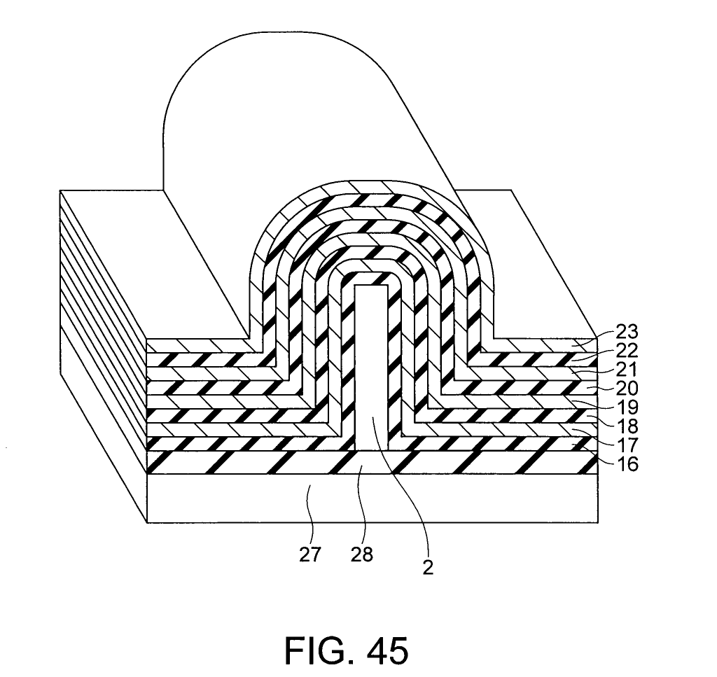

As shown in FIG. 45, a HfO₂ film 22 of 25 nm in thickness is then formed on the third polycrystalline silicon film 21 by CVD, for example. A 5-nm thick fourth polycrystalline silicon film 23 containing As or the like at a concentration of 2×10¹⁸ atoms/cm³ is then formed on the HfO₂ film 22 by CVD, for example.

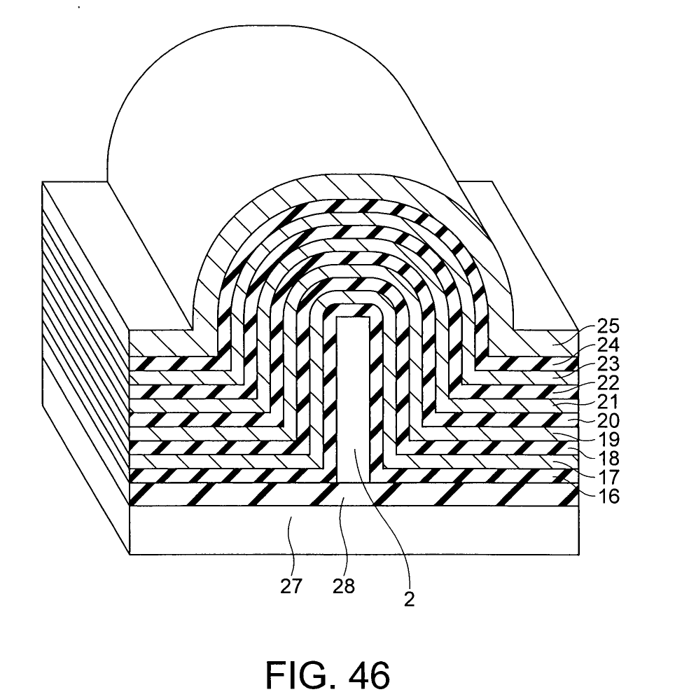

As shown in FIG. 46, a second LaAlO₃ film 24 of 30 nm in thickness is formed on the fourth polycrystalline silicon film 23 by CVD, for example. A W film 25 of 50 nm in thickness is then formed on the second LaAlO₃ film 24 by CVD, for example.

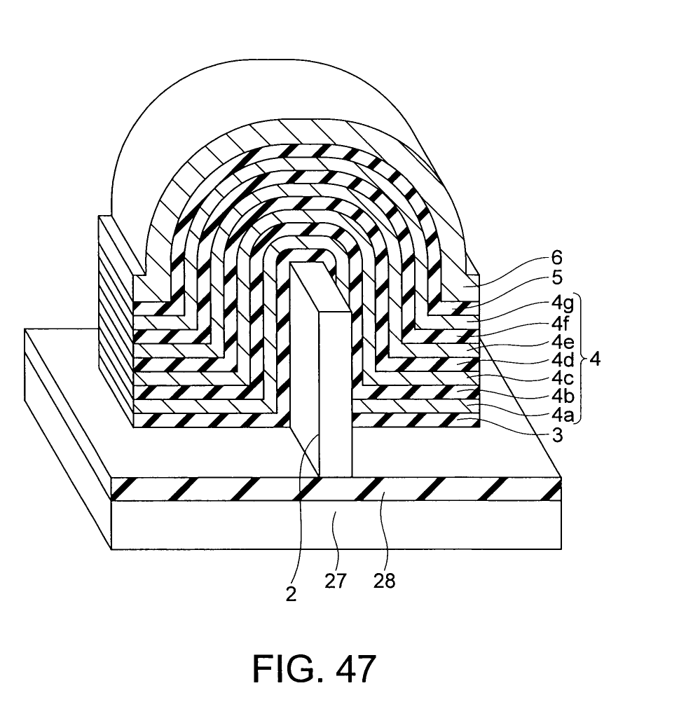

As shown in FIG. 47, patterning is then performed by RIE on the W film 25, the second LaAlO₃ film 24, the fourth polycrystalline silicon film 23, the HfO₂ film 22, the third polycrystalline silicon film 21, the Al₂O₃ film 20, the second polycrystalline silicon film 19, the Si₃N₄ film 18, the first polycrystalline silicon film 17, and the first LaAlO₃ film 16, so as to form the control gate electrode 6, the second insulating layer 5, the fourth conductor film 4g, the third inter-conductor insulating film 4f, the third conductor film 4e, the second inter-conductor insulating film 4d, the second conductor film 4c, the first inter-conductor insulating film 4b, the first conductor film 4a, and the first insulating layer 3.

After that, As ions are injected with an energy of 5 keV and at a concentration of 1×10¹⁵ atoms/cm², for example. Heat treatment is then carried out to form the source and drain regions. An interlayer insulating film forming procedure, a wiring procedure, and the likes are then carried out by known techniques. In this manner, the nonvolatile semiconductor memory element of this embodiment shown in FIG. 40 is completed.

In the nonvolatile semiconductor memory element of this embodiment, the first insulating layer 3, the charge accumulating layer 4, the second insulating layer 5, and the control gate electrode 6 are formed to cover the channel region. With this arrangement, the controllability of the control gate electrode on the potential of the channel region becomes higher, and a short-channel effect is restricted. Accordingly, it becomes possible to manufacture small-sized elements, and higher integration can be realized. Unlike the nonvolatile semiconductor memory element described in the first embodiment, the nonvolatile semiconductor memory element described in this embodiment has the first conductor film 4a formed to cover the first insulating layer 3, the first inter-conductor insulating film 4b formed to cover the first conductor film 4a, the second conductor film 4c formed to cover the first inter-conductor insulating film 4b, the second inter-conductor insulating film 4d formed to cover the second conductor film 4c, the third conductor film 4e formed to cover the second inter-conductor insulating film 4d, the third inter-conductor insulating film 4f formed to cover the third conductor film 4e, the fourth conductor film 4g formed to cover the third inter-conductor insulating film 4f, the second insulating layer 5 formed to cover the fourth conductor film 4g, and the control gate electrode 6 formed to cover the second insulating layer 5. This arrangement has the advantage that a greater margin can be allowed in the operating voltage, as in the nonvolatile semiconductor memory element described in the third embodiment.

On the other hand, each of the nonvolatile semiconductor memory elements described in the first to fifth embodiments is formed on a so-called bulk substrate, and has the advantage that the manufacturing procedures are simplified. In each of the nonvolatile semiconductor memory elements described in the first to third embodiments, surface flattening can be performed by CMP, for example, after the procedure for filling grooves with an insulating material such as silicon oxide to form the device isolating regions. As a result, the step portions between the surface of the channel region and the surfaces of the device isolating regions can be minimized.

Of the plate-like semiconductor region having the channel region and the source and drain regions in the nonvolatile semiconductor memory element described in this embodiment, a section perpendicular to the principal direction of the current flowing in the channel is longer when measured in the direction perpendicular to the surface of the semiconductor substrate than when measured in the direction parallel to the surface of the semiconductor substrate. However, this aspect is not essential in the present invention. Even if the lengths measured in both directions have the opposite relationship from the above described relationship or are the same, the same effects as above can be achieved.

In the nonvolatile semiconductor memory element described in this embodiment, the channel region is surrounded by the charge accumulating layer 4 at both sides and by the control gate electrode 6 from the above. However, the same effects as above can also be achieved, even if the channel region is surrounded by the charge accumulating layer 4 and the control gate electrode 6 only at both sides, for example. The same effects as above can still be achieved, even if the channel region is surrounded from above and below. Further, the same effects as above can be achieved, even if an element having a columnar shape is produced by forming the charge accumulating layer 4 and the control gate electrode 6 completely surrounding the channel forming region, for example.

If the charge accumulating layer 4 of this embodiment is replaced with the charge accumulating layer 4A of the second embodiment, the same effects as above can be achieved.

It is also possible to make the changes and modifications described in the foregoing embodiments to this embodiment, and to achieve the same effects as those of the foregoing embodiments.

### Seventh Embodiment

Next, an embodiment of a nonvolatile semiconductor memory device of the present invention is described.

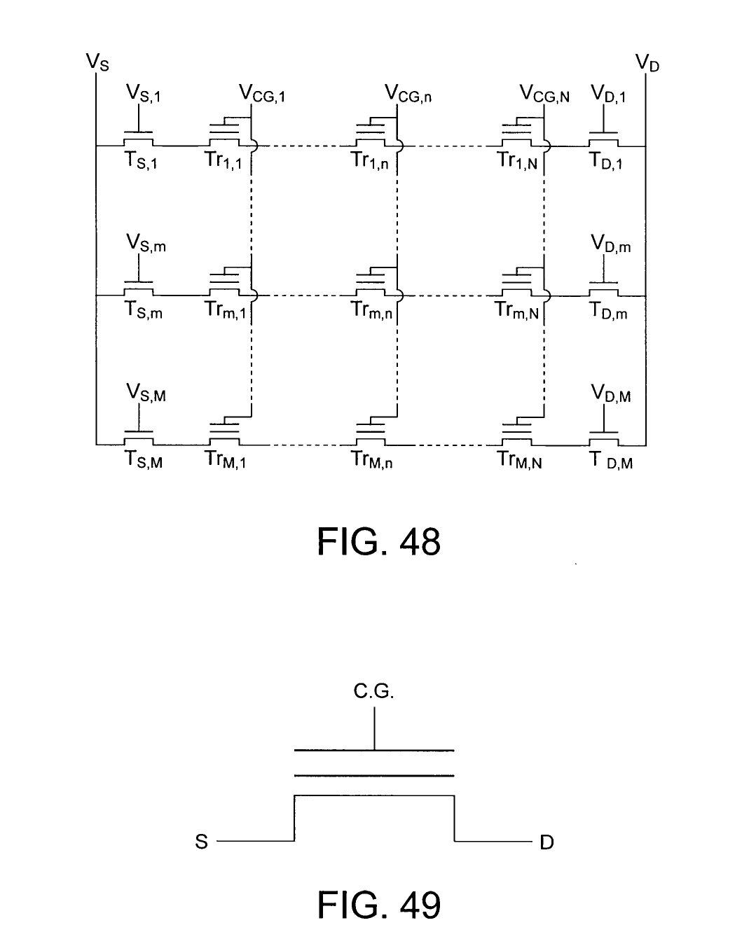

FIG. 48 is a circuit diagram of a nonvolatile semiconductor memory device of this embodiment. In the nonvolatile semiconductor memory device of this embodiment, nonvolatile semiconductor memory elements of one of the first to sixth embodiments are arranged in a lattice form. Those nonvolatile semiconductor memory elements are arranged in M rows and N columns, and the total number of nonvolatile semiconductor memory elements is M×N. In FIG. 48, each of the nonvolatile semiconductor memory elements of one of the first to sixth embodiments is represented by the circuit shown in FIG. 49. In FIG. 49, the terminals denoted by S and D are the source and drain, and the terminals denoted by C.G. is the control gate electrode. The terminal of the substrate is not shown.

In this embodiment, each nonvolatile semiconductor memory element is denoted by Tr_{i,j} (1≦i≦M, 1≦j≦N) as shown in FIG. 48. Among the nonvolatile semiconductor memory elements in the same row, the source and drain regions of each two adjacent elements are connected. The control gate electrodes of the nonvolatile semiconductor memory elements in the same column are connected to one another. In each row, the source of the nonvolatile semiconductor memory element in the first column and the drain of the nonvolatile semiconductor memory element in the Nth column are connected to common lines via field effect transistors T_{S,i} and T_{D,i} (1≦i≦M), respectively. The potentials of those lines are represented by V_{S} and V_{D}, respectively. The potentials of the gate electrodes of the field effect transistors T_{S,i} and T_{D,i} (1≦i≦M) are V_{S,i} and V_{D,i} (1≦i≦M), respectively. The threshold voltages of the field effect transistors T_{S,i} and T_{D,i} (1≦i≦M) do not need to be exactly the same, but may be substantially the same, which is Vₜₕ. The threshold voltages Vₜₕ is set between zero and a power supply voltage V_{DD}. The potentials of the control gate electrodes connected to one another in the jth column are V_{CG,j} (1≦j≦N). All the elements Tr_{i,j} (1≦i≦M, 1≦j≦N) have the same substrate potential. In FIG. 48, wires outside the area shown in FIG. 48 and the junction areas joined to the external wires are not shown. The nonvolatile semiconductor memory device of this embodiment can store information of L×M×N bits in total. Here, L represents the number of bits that can be stored in each one nonvolatile semiconductor memory element. The operations of this device will be described below.

Each of the nonvolatile semiconductor memory elements is an n-type nonvolatile semiconductor memory element, and the carriers in the charge accumulating layer are electrons. In the following, information writing, erasing, and reading to be performed on the nonvolatile semiconductor memory element Tr_{m,n} located in the mth row and the nth column are described. The same operations as described below can be performed in a case where each nonvolatile semiconductor memory element is a p-type nonvolatile semiconductor memory element or where the carriers in the charge accumulating layer are holes, if the polarity of the voltage is reversed. Here, m and n represent integers that satisfy the conditions, 1≦m≦M and 1≦n≦N.

First, information writing is performed in the following manner. As described in the foregoing embodiments, this nonvolatile semiconductor memory element can have various threshold voltages that are V_{TH,1}, V_{TH,2}, . . . , V_{TH,K} in ascending order. Here, K=2^{L} and V_{TH,k} (2≦k≦K−1) is set between zero and the driving voltage V_{DD}. The common substrate potential is set at zero. The potential V_{CG,j} (1≦j≦N) is higher than V_{TH,K}, and should be set at such a potential that does not cause tunnel current flowing through the inter-conductor insulating films or does not cause charge movement in the charge accumulating layer. With this arrangement, all the elements Tr_{i,j} (1≦i≦M, 1≦j≦N) are put into a conductive state. The potentials V_{S,i} and V_{D,i} (i≠m) are set at a lower value (zero, for example) than Vₜₕ, and the potentials V_{S,m} and V_{D,m} are set at a higher value (V_{DD}, for example) than Vₜₕ. With this arrangement, the transistors T_{S,i} and T_{D,i} (i≠m) are all put into a non-conductive state, and the transistors T_{S,m} and T_{D,m} are put into a conductive state. Here, V_{S} and V_{D} are zero. In this situation, the source and drain regions of Tr_{i,j} (i≠m, 1≦j≦N) are not connected to an external circuit, and are in a floating state. The source and drain regions of Tr_{m,j} (1≦j≦N) are connected to an external circuit, and the potentials are all zero. As a result, the potentials of the channel regions of Tr_{m,j} (1≦j≦N) becomes zero. If the common substrate is put into a floating state in this situation, and the potential V_{CG,n} is set at such a value that the threshold value of Tr_{m,n} becomes a desired value, the threshold voltage of Tr_{m,n} can be adjusted to a desired value. Here, V_{CG,j} (j≠n) is set higher than V_{TH,L}. However, V_{CG,j} is set at such a value that does not cause a tunnel current flowing through the inter-conductor insulating films or does not cause charge movement in the charge accumulating layer. Accordingly, the threshold voltages of Tr_{i,j} (1≦i≦M, j≠n) do not vary. As described above, the source and drain regions of Tr_{i,n} (i≠m) are in a floating state, and the substrate is also in a floating state. Accordingly, the channel regions of Tr_{i,n} (i≠m) are also in a floating state. Therefore, when V_{CG,n} is varied, the potentials of the channel regions of Tr_{i,n} (i≠m) vary with V_{CG,n} due to the capacitive coupling with the control gate electrode 6 via the first insulating layer 3, the charge accumulating layer 4, and the second insulating layer 5. Accordingly, the electric fields in the first and second insulating layers 3 and 5 and the inter-conductor insulating films of Tr_{i,n} (i≠m) do not become very large, and the tunnel current flowing through the inter-conductive insulating films is not generated, or the charges in the charge accumulating layer do not move. Therefore, the threshold voltages of Tr_{i,n} (i≠m) do not vary. In this manner, only the threshold voltage of Tr_{m,n} can be controlled, while the threshold voltages of the other elements Tr_{i,j}((i,j)≠(m,n)) are not varied. Thus, writing is performed.

Next, information erasing is described. Information erasing is performed simultaneously on the nonvolatile semiconductor memory elements located in the same column. In the following, erasing is to be performed on the information stored in the nonvolatile semiconductor memory elements located in the nth column. Here, n represents an integer that satisfies 1≦n≦N. The potential of the common substrate is set at zero. The potentials V_{S,i} and V_{D,i} (1≦i≦M) are set at a lower value (zero, for example) than Vₜₕ, and the potential V_{CG,j} (j≠n) is also set at zero, for example. The potential V_{CG,n} is set at such a low potential that all the electrons existing in the conductor films of the charge accumulating layer 4 are moved to the conductive film closest to the channel region by a tunnel current flowing through the inter-conductor insulating films. With this arrangement, the elements Tr_{i,j} (1≦i≦M, 1≦j≦N) are all put into a non-conductive state. Accordingly, the source and drain regions are put into a floating state, and the potential of the cannel region becomes zero, which is the same as the potential of the substrate. The electrons in the conductor films in the charge accumulating layers 4 of Tr_{i,j} (1≦i≦M, j≠n) do not move, and only the electrons in the conductor films in the charge accumulating layers 4 of Tr_{i,n} (1≦i≦M) move to the conductor films closest to the respective channel regions. In this manner, only the information stored in Tr_{i,n} (1≦i≦M) can be erased, while the information stored in Tr_{i,j} (1≦i≦M, j≠n) are not changed. To erase the information stored in all the elements Tr_{i,j} (1≦i≦M, 1≦j≦N) shown in FIG. 48, zero is applied to V_{S,i} and V_{D,i} (1≦i≦M) and V_{CG,j} (1≦j≦N), and such a sufficiently high potential is applied to the common substrate that all the electrons existing in the conductor films in the charge accumulating layers 4 are moved to the conductor films closest to the channel regions by the tunnel current flowing through the inter-conductor insulating film. In this manner, information erasing can be performed simultaneously on all the elements Tr_{i,j} (1≦i≦M, 1≦j≦N). Thus, operations are simplified, and the time required for erasing is shortened.

If erasing is performed by the technique described earlier, however, only the information stored in the nonvolatile semiconductor memory arranged in a certain column can be selectively erased, while the information stored in the nonvolatile semiconductor memory elements arranged in the other columns are not changed.

Writing and erasing are performed in the above described manners.

Next, reading is described. Reading the information stored in the Tr_{m,n} located in the mth row and in the nth column is performed in the following manner. Here, n and m represent an integer that satisfies 1≦m≦M and 1≦n≦N. The potential of the common substrate is set at zero. The potential V_{CG,j} (j≠n) is set higher than V_{TH,K}. However, the potential V_{CG,j} should be set at such a value that does not cause a tunnel current flowing through the inter-conductor insulating films, or does not cause charge movement in the charge accumulating layers. With this arrangement, the elements Tr_{i,j} (1≦i≦M, j≠N) are all put into a conductive state. The potential V_{S} is set at zero, and V_{D} is made equal to V_{DD}, for example. The potentials V_{S,i} and V_{D,i} (i≠m) are set at a lower value (zero, for example) than Vₜₕ, and the potentials V_{S,m} and V_{D,m} are set at V_{DD}, for example. In this situation, T_{S,i} and T_{D,i} (i≠m) are all put into a non-conductive state, and T_{S,m} and T_{D,m} are put into a conductive state. The source and drain regions of Tr_{i,j} (i≠m, 1≦j≦N) are not connected to an external circuit here, and are put into a floating state. Since the source and drain regions of Tr_{m,n} (1≦j≦N) are connected to an external circuit, the potentials of the source and drain regions of Tr_{m,j} (1≦j≦n) and the potential of the one of the source and drain regions of Tr_{m,n} located on the left-hand side in FIG. 48 are zero, and the potentials of the source and drain regions of Tr_{m,j} (n<j≦N) and the potential of the one of the source and drain regions of Tr_{m,n} located on the right-hand side in FIG. 48 are V_{DD}. With V_{CG,n} being set at V_{DD}, for example, the current generated in accordance with the threshold voltage of Tr_{m,n} flows from a terminal to which V_{D} is applied, into a terminal to which V_{S} is applied. Accordingly, the information stored in Tr_{m,n} can be read by detecting the current value.

It is also possible to read the information stored in Tr_{m,n} in the following manner. With V_{CG,n} being set at V_{DD}/2, for example, a check is made to determine whether there is a current flowing from a terminal to which V_{D} is applied, into a terminal to which V_{S} is applied. The result of the check indicates whether the threshold voltage of Tr_{m,n} is higher or lower than V_{DD}/2. If the threshold voltage of Tr_{m,n} is higher than V_{DD}/2, V_{CG,n} is set at 3×V_{DD}/4, and a check is then made to determine whether there is a current flowing from a terminal to which V_{D} is applied, into a terminal to which V_{S} is applied. If the threshold voltage of Tr_{m,n} is lower than V_{DD}/2, V_{CG,n} is set at V_{DD}/4, and a check is then made to determine whether there is a current flowing from a terminal to which V_{D} is applied, into a terminal to which V_{S} is applied. In this manner, the threshold voltage of Tr_{m,n} can be determined whether to be higher or lower than 3×V_{DD}/4 and V_{DD}/4. These procedures are repeated to determine the threshold voltage of Tr_{m,n}.

The former reading method has the advantage that the information stored in Tr_{m,n} can be read through one operation. The latter reading method has the advantage that detection can be performed after amplification by a sense amplifier or the like, and wrong reading can be prevented, as a check should be made only to determine whether there is a current flow.

In the above described manner, information of L bits can be stored in each one nonvolatile semiconductor memory element, and information of L×M×N bits can be stored in total.

It is also possible to make the changes and modifications described in the first to sixth embodiments to this embodiment, and to achieve the same effects as those of the first to sixth embodiments.

As described so far, in accordance with each of the embodiments of the present invention, the threshold voltage varies in a stepwise manner as the potential to be applied to the control gate electrode increases. Accordingly, two or more threshold voltage values can be generated, and a verifying operation can be eliminated. Thus, it is possible to provide high-performance nonvolatile semiconductor memory elements and a high-performance nonvolatile semiconductor memory device that are capable of performing higher-speed operations.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A nonvolatile semiconductor memory element comprising:
a semiconductor substrate;
a semiconductor region formed in the semiconductor substrate and containing an impurity of a first conductivity type;
source and drain regions formed at a distance from each other in the semiconductor region, and contain an impurity of a second conductivity type;
a first insulating layer formed on a portion of the semiconductor region, the portion being located between the source and drain regions;
a charge accumulating layer formed on the first insulating layer, and having a stacked structure including at least three conductor films and inter-conductor insulating films provided between the adjacent conductor films, a dielectric constant of any one of the inter-conductor insulating films located at a greater distance from the semiconductor substrate being higher than a dielectric constant of any one of the inter-conductor insulating films closer to the semiconductor substrate, a dielectric constant of each of the inter-conductor insulating films being lower than a dielectric constant of the first insulating layer;
a second insulating layer formed on the charge accumulating layer, and having a higher dielectric constant than the dielectric constant of any one of the inter-conductor insulating films; and
a conductor layer formed on the second insulating layer.

2. The element according to claim 1, wherein the conductor films in the charge accumulating layer are semiconductors containing impurities.

3. The element according to claim 1, wherein:
in the charge accumulating layer, any one of the conductor films at a greater distance from the first insulating layer has a larger film surface area than any one of the conductor films closer to the first insulating layer, and has a larger film surface area than any one of the inter-conductor insulating films closer to the first insulating layer;
any one of the inter-conductor insulating films at a greater distance from the first insulating layer has a larger film surface area than any one of the inter-conductor insulating films closer to the first insulating layer, and has a larger film surface area than any one of the conductor films closer to the first insulating layer;
the second insulating layer has a larger film surface area than the conductor film closest to the second insulating layer; and
the conductor layer has a larger film surface area than the second insulating layer.

4. The element according to claim 1, wherein the number of the conductor films is a power of two.

5. The element according to claim 1, wherein at least one of the first insulating layer and the second insulating layer contains metal.

6. The element according to claim 1, wherein at least one of the inter-conductor insulating films contains metal.

7. The element according to claim 1, wherein a dielectric constant of any one of the inter-conductor insulating films is higher than a dielectric constant of silicon oxide.

8. The element according to claim 1, wherein:
the number of the inter-conductor insulating films is three;
a first insulating film closest to the first insulating layer is made of silicon oxide, silicon nitride, or silicon oxynitride;
a second insulating film second closest to the first insulating layer is made of aluminum oxide;
a third insulating film furthest from the first insulating layer is made of hafnium oxide, zirconium oxide, hafnium silicate, or zirconium silicate; and
at least one of the first insulating layer and the second insulating layer is made of lanthanum aluminate.

9. The element according to claim 1, wherein equivalent oxide thicknesses of the inter-conductor insulating films are substantially equal to one another.

10. A nonvolatile semiconductor memory element comprising:
a semiconductor substrate;
a plate-like semiconductor region formed above the semiconductor substrate and containing an impurity of a first conductivity type;
source and drain regions formed at a distance from each other in a longitudinal direction of the plate-like semiconductor region, and containing an impurity of a second conductivity type;
a channel region provided in the plate-like semiconductor region located between the source region and the drain region;
a first insulating layer covering a pair of faces of the channel region facing each other;
a charge accumulating layer formed on a face of the first insulating layer on the opposite side from the channel region, and having a stacked structure including at least three conductor films and inter-conductor insulating films provided between the adjacent conductor films, a dielectric constant of any one of the inter-conductor insulating films located at a greater distance from the channel region being higher than a dielectric constant of any one of the inter-conductor insulating films closer to the channel region, a dielectric constant of each of the inter-conductor insulating films being lower than a dielectric constant of the first insulating layer;
a second insulating layer formed on a face of the charge accumulating layer on the opposite side from the first insulating layer, and having a higher dielectric constant than the dielectric constant of any one of the inter-conductor insulating films; and
a conductor layer formed on a face of the second insulating layer on the opposite side from the charge accumulating layer.

11. The element according to claim 10, wherein the conductor films in the charge accumulating layer are semiconductors containing impurities.

12. The element according to claim 10, wherein:
in the charge accumulating layer, any one of the conductor films at a greater distance from the first insulating layer has a larger film surface area than any one of the conductor films closer to the first insulating layer, and has a larger film surface area than any one of the inter-conductor insulating films closer to the first insulating layer;
any one of the inter-conductor insulating films at a greater distance from the first insulating layer has a larger film surface area than any one of the inter-conductor insulating films closer to the first insulating layer, and has a larger film surface area than any one of the conductor films closer to the first insulating layer;
the conductor film closest to the first insulating layer has a larger film surface area than the first insulating layer;
the second insulating layer has a larger film surface area than the conductor film closest to the second insulating layer; and
the conductor layer has a larger film surface area than the second insulating layer.

13. The element according to claim 10, wherein the number of the conductor films is a power of two.

14. A nonvolatile semiconductor memory element comprising:
a semiconductor substrate;
a semiconductor region formed in the semiconductor substrate and containing an impurity of a first conductivity type;
source and drain regions formed at a distance from each other on the semiconductor region, and containing an impurity of a second conductivity type;
a first insulating layer formed on a portion of the semiconductor region, the portion being located between the source and drain regions;
a charge accumulating layer formed on the first insulating layer, and having a stacked structure including at least two stacked charge storing insulating films, a dielectric constant of any one of the charge storing insulating films located at a greater distance from the semiconductor substrate being higher than a dielectric constant of any one of the charge storing insulating films closer to the semiconductor substrate, a dielectric constant of each of the charge storing insulating films being lower than a dielectric constant of the first insulating layer;
a second insulating layer formed on the charge accumulating layer, and having a higher dielectric constant than the dielectric constant of any one of the charge storing insulating films; and
a conductor layer formed on the second insulating layer.

15. The element according to claim 14, wherein:
in the charge accumulating layer, any one of the charge storing insulating films located at a greater distance from the first insulating layer has a larger film surface area than any one of the charge storing insulating films closer to the first insulating layer;
the charge storing insulating film closest to the first insulating layer has a larger film surface area than the first insulating layer;
the second insulating layer has a larger film surface area than the charge storing insulating film closest to the second insulating layer; and
the conductor layer has a larger film surface area than the second insulating layer.

16. The element according to claim 14, wherein a value obtained by adding 1 to the number of charge storing insulating films is a power of two.

17. The element according to claim 14, wherein at least one of the first insulating layer and the second insulating layer contains metal.

18. The element according to claim 14, wherein at least one of the charge storing insulating films contains metal.

19. The element according to claim 14, wherein a dielectric constant of any one of the charge storing insulating films is higher than a dielectric constant of silicon oxide.

20. The element according to claim 14, wherein:
the number of the charge storing insulating films is three;
a first insulating film closest to the first insulating layer is made of silicon oxide, silicon nitride, or silicon oxynitride;
a second insulating film second closest to the first insulating layer is made of aluminum oxide;
a third insulating film furthest from the first insulating layer is made of hafnium oxide, zirconium oxide, hafnium silicate, or zirconium silicate; and
at least one of the first insulating layer and the second insulating layer is made of lanthanum aluminate.

21. The element according to claim 14, wherein equivalent oxide thicknesses of the charge storing insulating films are substantially equal to one another.

22. A nonvolatile semiconductor memory element comprising:
a semiconductor substrate;
a plate-like semiconductor region formed on the semiconductor substrate and containing an impurity of a first conductivity type;
source and drain regions formed at a distance from each other in a longitudinal direction of the plate-like semiconductor region, and containing an impurity of a second conductivity type;
a channel region provided in the plate-like semiconductor region located between the source region and the drain region;
a first insulating layer covering a pair of faces of the channel region facing each other;
a charge accumulating layer formed a face of the first insulating layer on the opposite side from the channel region, and having a stacked structure including at least two stacked charge storing insulating films, a dielectric constant of any one of the charge storing insulating films located at a greater distance from the channel region being higher than a dielectric constant of any one of the charge storing insulating films closer to the channel region, a dielectric constant of each of the charge storing insulating films being lower than a dielectric constant of the first insulating layer;
a second insulating layer formed on a face of the charge accumulating layer on the opposite side from the first insulating layer, and having a higher dielectric constant than the dielectric constant of any one of the charge storing insulating films; and
a conductor layer formed on a face of the second insulating layer on the opposite side from the charge accumulating layer.

23. The element according to claim 22, wherein:
in the charge accumulating layer, any one of the charge storing insulating films located at a greater distance from the first insulating layer has a larger film surface area than any one of the charge storing insulating films closer to the first insulating layer;
the charge storing insulating film closest to the first insulating layer has a larger film surface area than the first insulating layer;
the second insulating layer has a larger film surface area than the charge storing insulating film closest to the second insulating layer; and
the conductor layer has a larger film surface area than the second insulating layer.

24. The element according to claim 22, wherein a value obtained by adding 1 to the number of charge storing insulating films is a power of two.

25. The element according to claim 22, wherein at least one of the first insulating layer and the second insulating layer contains metal.

26. The element according to claim 22, wherein at least one of the charge storing insulating films contains metal.

27. The element according to claim 22, wherein a dielectric constant of any one of the charge storing insulating films is higher than a dielectric constant of silicon oxide.

28. The element according to claim 22, wherein:
the number of the charge storing insulating films is three;
a first insulating film closest to the first insulating layer is made of silicon oxide, silicon nitride, or silicon oxynitride;
a second insulating film second closest to the first insulating layer is made of aluminum oxide;
a third insulating film furthest from the first insulating layer is made of hafnium oxide, zirconium oxide, hafnium silicate, or zirconium silicate; and
at least one of the first insulating layer and the second insulating layer is made of lanthanum aluminate.

29. The element according to claim 22, wherein equivalent oxide thicknesses of the charge storing insulating films are substantially equal to one another.

30. A nonvolatile semiconductor memory device comprising:
nonvolatile semiconductor memory elements being the same as the nonvolatile semiconductor memory element according to claim 1,
wherein the nonvolatile semiconductor memory elements are arranged in a lattice form,
the source and drain regions of any two adjacent ones of the nonvolatile semiconductor memory elements in the same row are connected to each other, and
the conductor layers of any two adjacent ones of the nonvolatile semiconductor memory elements in the same column are connected to each other.
